(19) United States
(12) Patent Application Publication
(10) Pub. No.: US 2026/0130072 A1
(43) Pub. Date: May 7, 2026

(54) DISPLAY APPARATUS AND ELECTRONIC APPARATUS INCLUDING THE SAME

(71) Applicant: Samsung Display Co., LTD., Yongin-si (KR)

(72) Inventors: YUN-MO CHUNG, Yongin-si (KR); DAEWOO LEE, Yongin-si (KR); JI-SIL LEE, Yongin-si (KR)

(21) Appl. No.: 19/374,005

(22) Filed: Oct. 30, 2025

(30) Foreign Application Priority Data
Nov. 4, 2024 (KR) 10-2024-0154393

(51) Int. Cl. H10K 59/131; H10K 59/124

(52) U.S. Cl. CPC H10K 59/131; H10K 59/124

(57) ABSTRACT

A display apparatus includes a display area implementing visible rays on a substrate and a peripheral area that is disposed on at least one side of the display area and has a non-display area, a scan clock line portion including a plurality of scan clock lines arranged sequentially in one direction, a sensing clock line portion including a plurality of sensing clock lines arranged sequentially in a direction different from the one direction, a stage portion including a plurality of stages connected to the plurality of scan clock lines and the plurality of sensing clock lines, and an insulating pattern portion disposed to overlap with the scan clock line portion or the sensing clock line portion.

This application claims priority to Korean Patent Application No.10-2024-0154393, filed on November 04, 2024, and all the benefits accruing therefrom under 35 U.S.C. §119, the content of which in its entirety is herein incorporated by reference.

### BACKGROUND

### 1. Field

Embodiments of the disclosure relate to a display apparatus and an electronic apparatus including the display apparatus.

### 2. Description of the Related Art

Recently, display apparatuses are being used for various purposes. Also, because thickness and weight of the display apparatus have been reduced, the utilization range of the display apparatuses is increasing.

Also, as fields of using display apparatuses increase and technology utilizing the display apparatus is developed, high image-quality characteristics and high-resolution characteristics are demanding in the display apparatus.

### SUMMARY

As display apparatuses become thinner in a form similar to a flat panel, steps of manufacturing processes increase and the complexity of the manufacturing processes is also increasing.

Accordingly, there are limitations in implementing high-image quality display apparatuses through stabilized manufacturing processes.

Embodiments of the disclosure provide a display apparatus with improved image quality characteristics and an electronic apparatus including the display apparatus.

In an embodiment of the disclosure, a display apparatus includes a display area implementing visible rays on a substrate and a peripheral area that is disposed on at least one side of the display area and has a non-display area, a scan clock line portion including a plurality of scan clock lines arranged sequentially in one direction, a sensing clock line portion including a plurality of sensing clock lines arranged sequentially in a direction different from the one direction, a stage portion including a plurality of stages connected to the plurality of scan clock lines and the plurality of sensing clock lines, and an insulating pattern portion disposed to overlap with the scan clock line portion or the sensing clock line portion.

In an embodiment, the scan clock line portion and the sensing clock line portion may be arranged in one direction, the plurality of sensing clock lines of the sensing clock line portion may be disposed sequentially in the one direction, and the plurality of scan clock lines of the scan clock line portion may be disposed sequentially in a direction opposite to the one direction.

In an embodiment, the scan clock line portion and the sensing clock line portion may be arranged in one direction, a first sensing clock line to an N-th sensing clock line from among the plurality of sensing clock lines may be disposed in the one direction, and a first scan clock line to an N-th scan clock line from among the plurality of scan clock lines may be disposed sequentially in a direction opposite to the one direction.

In an embodiment, a structure in which the plurality of sensing clock lines of the sensing clock line portion are sequentially arranged may be symmetrical with a structure in which the plurality of scan clock lines of the scan clock line portion are sequentially arranged.

In an embodiment, a distance between one scan clock line and one sensing clock line that are connected to one of the plurality of stages may have a different value from a distance between one scan clock line and one sensing clock line that are connected to another stage of the plurality of stages.

In an embodiment, the insulating pattern portion may be disposed to correspond to a center region between the scan clock line portion and the sensing clock line portion so as to overlap with at least some of the plurality of scan clock lines and at least some of the plurality of sensing clock lines.

In an embodiment, a center of the insulating pattern portion may be disposed to be misaligned from a center region between the scan clock line portion and the sensing clock line portion.

In an embodiment, one or more insulating layers may be disposed between the insulating pattern portion and each of the scan clock line portion and the sensing clock line portion.

In an embodiment, each of the plurality of stages in the stage portion may transfer one or more scan signals and one or more sensing signals to a pixel of the display area by signals received through the plurality of scan clock lines and the plurality of sensing clock lines.

In another embodiment of the disclosure, an electronic apparatus includes a controller configured to generate one or more signals, and a display apparatus receiving the one or more signals from the controller and displaying information, where the display apparatus includes a scan clock line portion, a sensing clock line portion, and a stage portion that are arranged to receive a signal from the controller and transfer a signal for displaying information on the display apparatus, the scan clock line portion includes a plurality of scan clock lines that are sequentially arranged in one direction, the sensing clock line portion includes a plurality of sensing clock lines that are sequentially arranged in a direction different from the one direction, the stage portion includes a plurality of stages connected to the plurality of scan clock lines and the plurality of sensing clock lines, and an insulating pattern portion is arranged to overlap with the scan clock line portion or the sensing clock line portion.

In another embodiment of the present disclosure, an electronic apparatus includes a controller configured to generate one or more signals, and a display apparatus receiving the one or more signals from the controller and displaying information, where the display apparatus includes a scan clock line portion, a sensing clock line portion, and a stage portion that are arranged to receive a signal from the controller and transfer a signal for displaying information on the display apparatus, the scan clock line portion includes a plurality of scan clock lines that are sequentially arranged in one direction, the sensing clock line portion includes a plurality of sensing clock lines that are sequentially arranged in the one direction, the stage portion includes a plurality of stages connected to the plurality of scan clock lines and the plurality of sensing clock lines, an insulating pattern portion is disposed to overlap with the scan clock line portion or the sensing clock line portion, and in a region overlapping at least the insulating pattern portion, one sensing clock line is disposed between two scan clock lines next (adjacent) to each other from among the plurality of scan clock lines.

In another embodiment of the disclosure, a display apparatus includes a display area implementing visible rays on a substrate and a peripheral area that is disposed on at least one side of the display area and has a non-display area, a scan clock line portion including a plurality of scan clock lines arranged sequentially in one direction, a sensing clock line portion including a plurality of sensing clock lines arranged sequentially in the one direction, a stage portion including a plurality of stages connected to the plurality of scan clock lines and the plurality of sensing clock lines, and an insulating pattern portion disposed to overlap with the scan clock line portion or the sensing clock line portion, where, in the region overlapping at least the insulating pattern portion, one sensing clock line is disposed between two scan clock lines next (adjacent) to each other from among the plurality of scan clock lines.

In an embodiment, in the region overlapping at least the insulating pattern portion, one scan clock line may be disposed between two sensing clock lines next (adjacent) to each other from among the plurality of sensing clock lines.

In an embodiment, in the region overlapping at least the insulating pattern portion, each of the plurality of scan clock lines of the scan clock line portion and each of the plurality of sensing clock lines of the sensing clock line portion may be sequentially arranged alternately with each other.

In an embodiment, the scan clock line portion and the sensing clock line portion may be disposed in the one direction, and a first sensing clock line to an N-th sensing clock line from among the plurality of sensing clock lines and a first scan clock line and an N-th scan clock line from among the plurality of scan clock lines may be sequentially arranged in the one direction alternately with each other.

In an embodiment, the insulating pattern portion may be disposed to correspond to a center region between the scan clock line portion and the sensing clock line portion so as to overlap with at least some of the plurality of scan clock lines and at least some of the plurality of sensing clock lines.

In an embodiment, a center of the insulating pattern portion may be disposed to be misaligned from a center region between the scan clock line portion and the sensing clock line portion.

In an embodiment, all of the plurality of scan clock lines and all of the plurality of sensing clock lines may be sequentially arranged in the one direction alternately with each other.

In an embodiment, each of the plurality of stages in the stage portion may transfer to a pixel of the display area one or more scan signals and one or more sensing signals by signals received through the plurality of scan clock lines and the plurality of sensing clock lines.

In an embodiment, the pixel may include one or more organic light-emitting devices implementing visible rays.

Other embodiments, features and advantages other than those described above will become apparent from the following detailed description of the drawings, claims and disclosure.

### BRIEF DESCRIPTION OF THE DRAWINGS

The above and other embodiments, advantages and features of this disclosure will become more apparent by describing in further detail embodiments thereof with reference to the accompanying drawings, in which:

FIG. 1 is a plan view of an embodiment of a display apparatus according to the disclosure;

FIG. 2 is a schematic cross-sectional view of region K taken along line II-II of FIG. 1;

FIG. 3 is a schematic block diagram for illustrating the configuration of FIG. 2;

FIGS. 4 and 5 are schematic cross-sectional views showing a modified embodiment of the configuration shown in FIG. 2;

FIG. 6 is a plan view of another embodiment of a display apparatus according to the disclosure;

FIG. 7 is a schematic cross-sectional view of region K taken along line VII-VII of FIG. 6;

FIGS. 8 and 9 are schematic cross-sectional views showing an alternative embodiment of the configuration shown in FIG. 7;

FIG. 10 is a schematic plan view of another embodiment of a display apparatus according to the disclosure;

FIG. 11 is a schematic cross-sectional view of region K taken along line XI-XI of FIG. 10;

FIG. 12 is a schematic plan view of another embodiment of a display apparatus according to the disclosure;

FIG. 13 is a block diagram of the display apparatus of FIG. 12;

FIG. 14 is a circuit diagram schematically showing one sub-pixel in the display apparatus of FIG. 12;

FIG. 15 is a schematic cross-sectional view of region K taken along line XV-XV of FIG. 12;

FIG. 16 is a schematic cross-sectional view of region P taken along line XVI-XVI of FIG. 12;

FIG. 17 is a schematic plan view of another embodiment of a display apparatus according to the disclosure;

FIG. 18 is a schematic cross-sectional view of region K taken along line XVIII-XVIII of FIG. 17;

FIG. 19 is a schematic cross-sectional view of another embodiment of a display apparatus according to the disclosure; and

FIG. 20 is a view illustrating an embodiment of an electronic apparatus as a smartphone.

### DETAILED DESCRIPTION

As the disclosure allows for various changes and numerous embodiments, particular embodiments will be illustrated in the drawings and described in detail in the written description. The attached drawings for illustrating embodiments are referred to in order to gain a sufficient understanding, the merits thereof, and the objectives accomplished by the implementation. However, the embodiments may have different forms and should not be construed as being limited to the descriptions set forth herein.

While such terms as "first," "second," etc., may be used to describe various components, such components are not be limited to the above terms. The above terms are used only to distinguish one component from another.

An expression used in the singular encompasses the expression of the plural, unless it has a clearly different meaning in the context.

In the specification, it is to be understood that the terms "including," "having," and "comprising" are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

It will be understood that when a layer, region, or component is referred to as being "formed on" another layer, region, or component, it may be directly or indirectly formed on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, the following disclosure is not limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When an illustrative embodiment is implemented differently, a predetermined process order may be performed differently from the described order. For example, two consecutively described processes may be performed substantially at the same time or performed in an order opposite to the described order.

The embodiments will be described below in more detail with reference to the accompanying drawings. Those components that are the same or are in correspondence are rendered the same reference numeral regardless of the figure number, and redundant explanations are omitted.

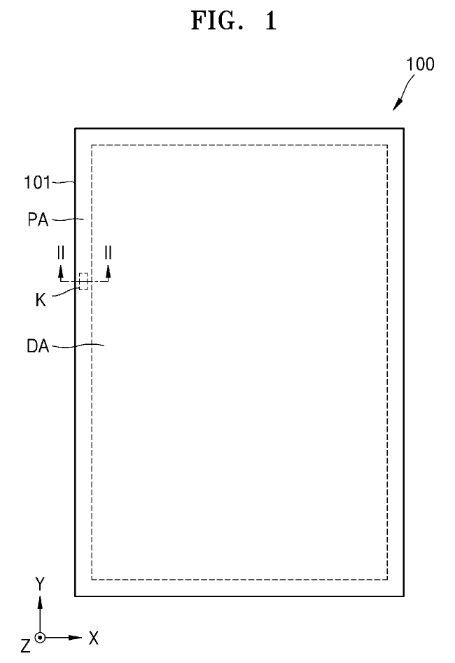

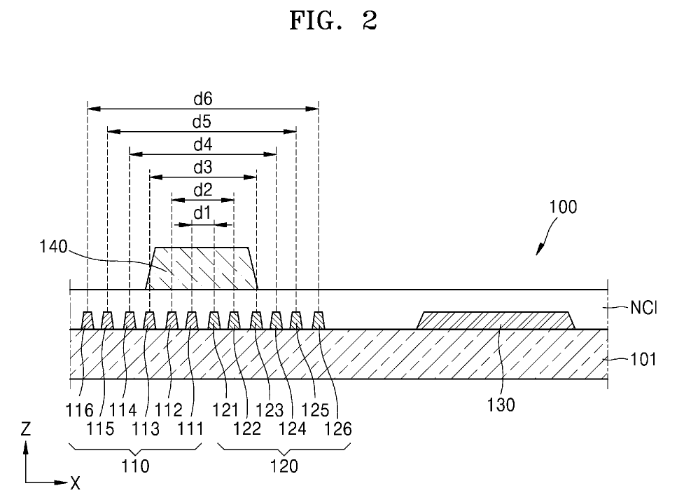

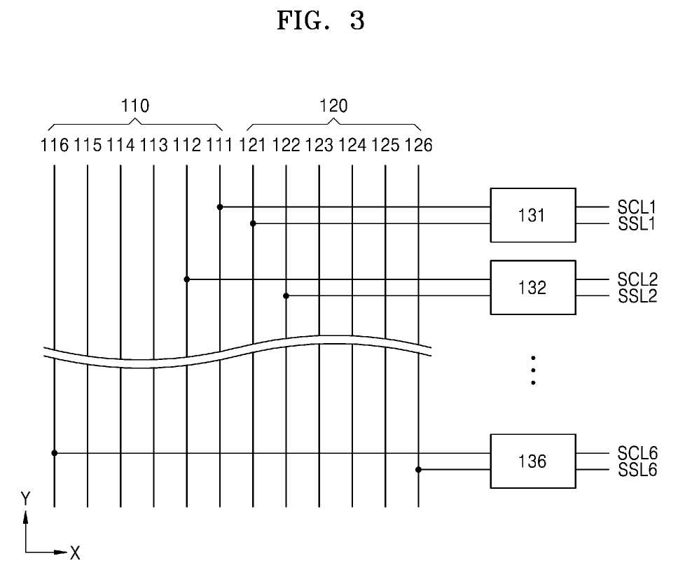

FIG. 1 is a plan view of an embodiment of a display apparatus according to the disclosure. FIG. 2 is a schematic cross-sectional view of region K taken along line II-II of FIG. 1. FIG. 3 is a schematic block diagram for illustrating the configuration of FIG. 2.

A display apparatus 100 may include a scan clock line portion 110, a sensing clock line portion 120, a stage portion 130, and an insulating pattern portion 140.

The insulating pattern portion 140 may perform various functions, for example, may be formed to support a manufacturing device (e.g., mask member) for forming one or more layers in the display apparatus 100, and to this end, may be formed to have a set height. In another embodiment, the insulating pattern portion 140 may be used for another function, for example, a partition wall that restricts formation of layers (e.g., insulating material or encapsulation material) next (adjacent) to each other.

Referring to FIG. 1, the display apparatus 100 may include a display area DA and a peripheral area PA defined on a substrate 101.

The display area DA may include one or more display devices, e.g., organic light-emitting devices, so as to display images. In another embodiment, the display device may include one of a quantum dot light-emitting device, a liquid crystal display device, and other various kinds of display devices. In an embodiment, an embodiment in which the display device is an organic light-emitting device is described, but other kinds of display devices may be also applied.

In some embodiments, a plurality of pixels may be disposed in the display area DA, a pixel may include a plurality of sub-pixels, and one or more display devices may be disposed in the sub-pixel.

The peripheral area PA may be formed around the display area DA. The peripheral area PA may include a non-display area, for example, a non-display area may be formed to surround the display area DA. In some embodiments, in another alternative embodiment, the peripheral area PA or the non-display area in the peripheral area PA may be next (adjacent) to only one side or opposite side surfaces of the display area DA.

A drive circuit region generating various signals for operating pixels in the display area DA may be disposed in the peripheral area PA, and the drive circuit region may include one or more drive circuit portions. In some embodiments, in detail, the scan clock line portion 110, the sensing clock line portion 120, the stage portion 130, and the insulating pattern portion 140 may be disposed in the peripheral area PA.

In some embodiments, although not shown in the drawings, the display area DA may include scan signal lines (e.g., SCL1 to SCL6 in FIG. 3) and sensing signal lines (e.g., SSL1 to SSL6) connected to the sub-pixels, as well as the sub-pixels. In some embodiments, one or more data lines and one or more driving voltage lines may be disposed in the sub-pixel.

In some embodiments, the scan clock line portion 110, the sensing clock line portion 120, and the stage portion 130 may be included in a scan clock driving unit.

The substrate 101 may include various materials. In some embodiments, the substrate 101 may include glass, metal, an organic material, or other materials.

In an alternative embodiment, the substrate 101 may include a flexible material. In an embodiment, the substrate 101 may be easily curved, bendable, foldable, or rollable, for example.

In an alternative embodiment, the substrate 101 may include ultra-thin glass, metal, or plastic. In an embodiment, when plastic is used, the substrate 101 may include polyimide (“PI”), and in another detailed examples, the substrate 101 may include at least one of polystyrene, polyvinyl alcohol, polymethyl methacrylate, polyether sulfone, polyacrylate, polyetherimide, polyethylene naphthalate, polyethylene terephthalate, polyphenylene sulfide, polyarylate, polycarbonate, triacetate cellulose, and cellulose acetate propionate, for example.

In some embodiments, the substrate 101 may include one or more layers, for example, a multi-layered structure. In an embodiment, the substrate 101 may include an organic layer (e.g., a resin-based material) and an inorganic layer, and in more detail, may include a structure in which an inorganic layer is disposed between two organic layers, for example.

The scan clock line portion 110 may include a plurality of scan clock lines, e.g., first to sixth scan clock lines 111 to 116. The number of six is an example, and the number may be less than or greater than six.

The sensing clock line portion 120 may include a plurality of sensing clock lines, e.g., first to sixth sensing clock lines 121 to 126. The number of six is an example, and the number may be less than or greater than six.

The scan clock line portion 110 and the sensing clock line portion 120 may be arranged in one direction (e.g., X-axis direction), and in detail, the scan clock line portion 110 and the sensing clock line portion 120 may be spaced apart from each other in a width direction of each line portion and may be arranged in one direction (e.g., X-axis direction).

Each of the first to sixth sensing clock lines 121 to 126 of the sensing clock line portion 120 may be arranged in one direction. In an embodiment, the first to sixth sensing clock lines 121 to 126 may be sequentially arranged based on one direction (positive direction in X-axis or a direction from left to right based on FIG. 2), for example.

In other words, the first sensing clock line 121, the second sensing clock line 122, the third sensing clock line 123, the fourth sensing clock line 124, the fifth sensing clock line 125, and the sixth sensing clock line 126 may be sequentially arranged while being spaced apart from each other based on one direction (the positive direction in X-axis or the direction from left to right based on FIG. 2).

Each of the first to sixth scan clock lines 111 to 116 of the scan clock line portion 110 may be arranged in one direction. In an embodiment, the first to sixth scan clock lines 111 to 116 may be sequentially arranged based on one direction (negative direction in X-axis or a direction from right to left based on FIG. 2), for example.

In other words, the first scan clock line 111, the second scan clock line 112, the third scan clock line 113, the fourth scan clock line 114, the fifth scan clock line 115, and the sixth scan clock line 116 may be sequentially arranged while being spaced apart from each other based on one direction (the negative direction in X-axis or the direction from right to left based on FIG. 2).

In other words, the first to sixth sensing clock lines 121 to 126 of the sensing clock line portion 120 and the first to sixth scan clock lines 111 to 116 of the scan clock line portion 110 may be arranged symmetrically with each other in the transverse direction based on the drawings.

In some embodiments, in other words, a distance between clock lines connected to one stage of the stage portion 130 may be different from a distance between clock lines connected to another stage. In an embodiment, a distance d1 between the first sensing clock line 121 and the first scan clock line 111, a distance d2 between the second sensing clock line 122 and the second scan clock line 112, a distance d3 between the third sensing clock line 123 and the third scan clock line 113, a distance d4 between the fourth sensing clock line 124 and the fourth scan clock line 114, a distance d5 between the fifth sensing clock line 125 and the fifth scan clock line 115, and a distance d6 between the sixth sensing clock line 126 and the sixth scan clock line 116 may be different from one another, for example.

In an embodiment, the distance d6 may be greater than the distance d1, for example. In some embodiments, the distance d1, the distance d2, the distance d3, the distance d4, the distance d5, and the distance d6 may become greater in the stated order.

In some embodiments, although not shown in the drawings, in an alternative embodiment, the first to sixth sensing clock lines 121 to 126 may be sequentially arranged from the right side to the left side, and the first to sixth scan clock lines 111 to 116 of the scan clock line portion 110 may be sequentially arranged from the left side to the right side, and in this case, the distance d6 may be less than the distance d1. In some embodiments, the distance d1, the distance d2, the distance d3, the distance d4, the distance d5, and the distance d6 may become less in the stated order.

The stage portion 130 may be disposed to be spaced apart from the scan clock line portion 110 and the sensing clock line portion 120, and may be connected via one or more connection lines.

In an embodiment, the stage portion 130, the scan clock line portion 110, and the sensing clock line portion 120 may be arranged in one direction (X-axis direction), for example. In more detail, as shown in the drawings, the scan clock line portion 110 may be disposed to face one side of the sensing clock line portion 120, and the stage portion 130 may be disposed to face an opposite side of the sensing clock line portion 120. This is an illustrative embodiment, and the stage portion 130 may be disposed on at least one side of the scan clock line portion 110 or the sensing clock line portion 120.

Although not shown in the drawings, the stage portion 130 may include a plurality of stages, e.g., six stages. FIG. 3 shows three stages for convenience of description, for example, a first stage 131, a second stage 132, and a sixth stage 136 are shown, and third, fourth, and fifth stages (not shown) are omitted.

The first stage 131 may output a first scan signal to a first scan signal line SCL1 and a first sensing signal to a first sensing signal line SSL1.

The second stage 132 may output a second scan signal to a second scan signal line SCL2 and a second sensing signal to a second sensing signal line SSL2.

The sixth stage 136 may output a sixth scan signal to a sixth scan signal line SCL6 and a sixth sensing signal to a sixth sensing signal line SSL6.

The respective output signals may be transferred to the pixels in the display area DA.

The stages included in the stage portion 130 may be respectively connected to the lines of the scan clock line portion 110 and the lines of the sensing clock line portion 120.

The first scan clock line 111 of the scan clock line portion 110 and the first sensing clock line 121 of the sensing clock line portion 120 may be electrically connected to the first stage 131 respectively via conductive connection lines.

The second scan clock line 112 of the scan clock line portion 110 and the second sensing clock line 122 of the sensing clock line portion 120 may be electrically connected to the second stage 132 respectively via conductive connection lines.

The sixth scan clock line 116 of the scan clock line portion 110 and the sixth sensing clock line 126 of the sensing clock line portion 120 may be electrically connected to the sixth stage 136 respectively via conductive connection lines.

Although not shown in the drawings, in an alternative embodiment, one or more clock line portions electrically connected to the stage portion 130 may be further provided, for example, a carry clock line portion and a global clock line portion may be included, each of which includes a plurality of clock lines. The plurality of clock lines may be respectively connected to the plurality of stages 131, 132, and 136 of the stage portion 130.

Each of the plurality of stages in the stage portion 130 may be connected to at least one scan signal line to apply scan signals, and may be connected to a sensing signal line to apply sensing signals.

In an embodiment, the first stage 131 of the stage portion 130 may output a first scan signal to the first scan signal line SCL1 and a first sensing signal to the first sensing signal line SSL, based on the first sensing clock signal received through the first sensing clock line 121 and the first scan clock signal received through the first scan clock line 111, for example. In an alternative embodiment, the first stage 131 may be connected to a carry clock line portion and a global clock line portion, and in this case, may output the first scan signal and the first sensing signal based on the first sensing clock signal and the first scan clock signal, and one or more carry clock signals or one or more global clock signals.

In some embodiments, in an illustrative embodiment, the first stage 131 may output the first sensing signal to the first sensing signal line SSL1 based on the first sensing clock signal received through the first sensing clock line 121, and output the first scan signal to the first scan signal line SCL1 based on the first scan clock signal received through the first scan clock line 111.

In some embodiments, for example, the second stage 132 of the stage portion 130 may output a second scan signal to the second scan signal line SCL2 and a second sensing signal to the second sensing signal line SSL, based on a second sensing clock signal received through the second sensing clock line 122 and the second scan clock signal received through the second scan clock line 112. In an alternative embodiment, the second stage 132 may be connected to a carry clock line portion and a global clock line portion, and in this case, may output the second scan signal and the second sensing signal based on the second scan clock signal and the second sensing clock signal, and one or more carry clock signals or one or more global clock signals.

In some embodiments, in an illustrative embodiment, the second stage 132 may output the second sensing signal to the second sensing signal line SSL2 based on the second sensing clock signal received through the second sensing clock line 122, and output the second scan signal to the second scan signal line SCL2 based on the second scan clock signal received through the second scan clock line 112.

In some embodiments, for example, the sixth stage 136 of the stage portion 130 may output a sixth scan signal to the sixth scan signal line SCL6 and a sixth sensing signal to the sixth sensing signal line SSL6, based on a sixth sensing clock signal received through the sixth sensing clock line 126 and the sixth scan clock signal received through the sixth scan clock line 116. In an alternative embodiment, the sixth stage 136 may be connected to a carry clock line portion and a global clock line portion, and in this case, may output the sixth scan signal and the sixth sensing signal based on the sixth scan clock signal and the sixth sensing clock signal, and one or more carry clock signals or one or more global clock signals.

In some embodiments, in an illustrative embodiment, the sixth stage 136 may output the sixth sensing signal to the sixth sensing signal line SSL6 based on the sixth sensing clock signal received through the sixth sensing clock line 126, and output the sixth scan signal to the sixth scan signal line SCL6 based on the sixth scan clock signal received through the sixth scan clock line 116.

Although the third to fifth stages (not shown) are not shown, the third to fifth stages may be understood based on the structures of the first, second, and sixth stages 131, 132, and 136, and thus, detailed descriptions are omitted.

The insulating pattern portion 140 may be disposed to overlap with at least a region of the scan clock line portion 110 or the sensing clock line portion 120.

In an alternative embodiment, an insulating layer NCI may be formed on the scan clock line portion 110 and the sensing clock line portion 120, and the insulating pattern portion 140 may be insulated from the scan clock line portion 110 and the sensing clock line portion 120 by the insulating layer NCI.

In an alternative embodiment, the insulating layer NCI may be formed on the stage portion 130 to cover the stage portion 130.

In an alternative embodiment, another insulating layer may be formed on the insulating layer NCI so as to correspond to at least one side surface or the upper surface of the insulating pattern portion 140.

The insulating pattern portion 140 may be disposed to overlap with at least a region of the scan clock line portion 110 or the sensing clock line portion 120.

The insulating pattern portion 140 may have various functions, for example, may form a manufacturing device (e.g., mask member) for forming one or more layers in the display apparatus 100, and to this end, may be formed to have a set height. In another embodiment, the insulating pattern portion 140 may be used for another function, for example, may be a partition wall that restricts formation of layers (e.g., insulating material or encapsulation material) next (adjacent) to each other.

The insulating pattern portion 140 may include various insulation materials, e.g., an organic material. In some embodiments, the insulating pattern portion 140 may be formed to have a single layer or multi-layers.

Referring to FIG. 2, the insulating pattern portion 140 may be disposed to overlap the first to third scan clock lines 111 to 113 of the scan clock line portion 110 and the first to third sensing clock lines 121 to 123 of the sensing clock line portion 120.

A direction in which the first to sixth scan clock lines 111 to 116 of the scan clock line portion 110 are sequentially arranged is opposite to that of the first to sixth sensing clock lines 121 to 126 of the sensing clock line portion 120.

In an embodiment, the arrangement type of the first to sixth scan clock lines 111 to 116 of the scan clock line portion 110 of the embodiment may be symmetrical with that of the first to sixth sensing clock lines 121 to 126 of the sensing clock line portion 120, for example.

As such, a variation in image quality characteristic (e.g., increase in luminance) through the first to sixth scan clock lines 111 to 116 of the scan clock line portion 110 and a variation in image quality characteristic (e.g., decrease in luminance) through the first to sixth sensing clock lines 121 to 126 of the sensing clock line portion 120 may offset each other, and thus, defects of inconsistent luminance due to external and internal environmental issues in use of the display apparatus 100 may be reduced.

In some embodiments, when the display apparatus 100 is used in an environment of relatively high temperature and relatively high humidity, moisture may infiltrate through the edges, and the insulating pattern portion 140 is closer to the edge of the display apparatus 100, rather than the center, and thus, vertical isolation may occur in the region next (adjacent) to the insulating pattern portion 140. Due to the vertical isolation, the capacitance may change in the region next (adjacent) to the insulating pattern portion 140, and in detail, the capacitance of the scan clock line portion 110 or the sensing clock line portion 120 may increase.

In some embodiments, in an illustrative embodiment, when the capacitance increases in the region next (adjacent) to each clock line of the scan clock line portion 110, a voltage applied to a gate of a transistor that drives pixels via the scan signal lines increases, and accordingly, the luminance of the display device may increase. In some embodiments, in another detailed example, when the capacitance increases in a region next (adjacent) to each clock line of the sensing clock line portion 120, a voltage applied to a gate of a transistor related to initialization of connected pixels increases, and accordingly, the luminance of the display device may decrease.

In some embodiments, the increase or decrease in the luminance of the clock lines may vary depending on the order, for example, a range of increase in the luminance may be greater according to the order of the first to sixth scan clock lines 111 to 116 of the scan clock line portion 110 and a range of decrease in the luminance may be greater according to the order of the first to sixth sensing clock lines 121 to 126 of the sensing clock line portion 120. In this case, when the sixth scan clock line 116 and the first sensing clock line 121 are next (adjacent) to each other, the luminance variation increases and generation of image quality defect on the screen may increase. In an embodiment, the first to sixth scan clock lines 111 to 116 of the scan clock line portion 110 are sequentially arranged in one direction, and the first to sixth sensing clock lines 121 to 126 of the sensing clock line portion 120 may be disposed in opposite direction. Accordingly, the first scan clock line 111 and the first sensing clock line 121 may be disposed next (adjacent) to each other.

As a result, the increase in the luminance due to the increase in the capacitance of the first to sixth scan clock lines 111 to 116 of the scan clock line portion 110 and decrease in the luminance due to the increase in the capacitance of the first to sixth sensing clock lines 121 to 126 of the sensing clock line portion 120 may be reduced, and thus, luminance characteristics may be improved.

In some embodiments, in FIG. 2, the first to third scan clock lines 111 to 113 of the scan clock line portion 110 and the first to third sensing clock lines 121 to 123 of the sensing clock line portion 120 may be disposed to overlap the insulating pattern portion 140. In an illustrative embodiment, the insulating pattern portion 140 may be disposed to overlap the central region between the scan clock line portion 110 and the sensing clock line portion 120.

As such, a variation in the capacitance of the first to third scan clock lines 111 to 113 overlapping the insulating pattern portion 140 is relatively large and a variation in the capacitance of the first to third sensing clock lines 121 to 123 overlapping the insulating pattern portion 140 may be relatively large. As such, the region having relatively large variation in the luminance increase and the region having relatively large variation in the luminance decrease may be disposed to overlap, and accordingly, inconsistency in the luminance in each of the pixels in the display apparatus 100, e.g., defects such as moiré, etc., may be reduced.

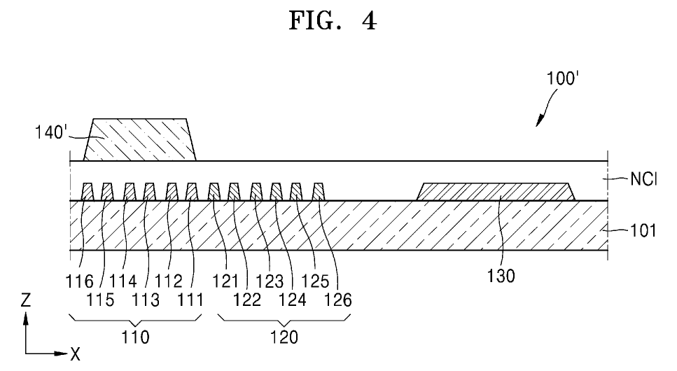

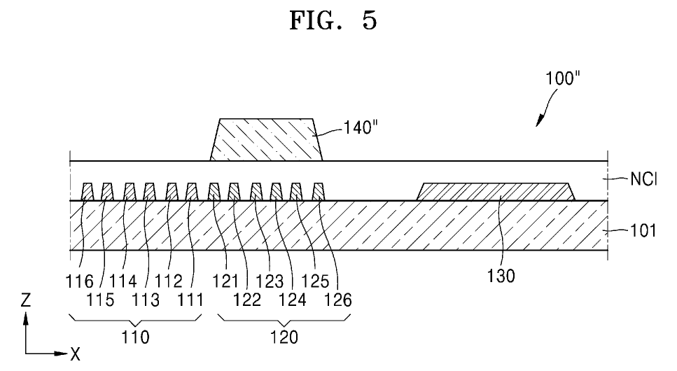

FIGS. 4 and 5 are schematic cross-sectional views showing a modified embodiment of the configuration shown in FIG. 2.

Referring to FIG. 4, a display apparatus 100' may have different arrangement of an insulating pattern portion 140' from that of FIG. 2. In an embodiment, the insulating pattern portion 140' may be disposed to overlap the first to sixth scan clock lines 111 to 116 of the scan clock line portion 110, for example. In an illustrative embodiment, a center of the insulating pattern portion 140' may be disposed to be misaligned with the central area between the scan clock line portion 110a and the sensing clock line portion 120.

Here, from among the lines of the sensing clock line portion 120, the first sensing clock line 121 may be closest to the insulating pattern portion 140'. As such, inconsistency in the luminance increase of the scan clock line portion 110 may be reduced and the first sensing clock line 121 having less reduction in the luminance of the sensing clock line portion 120 is next (adjacent) to the insulating pattern portion 140', and thus it may be controlled to reduce the variation in the luminance decrease even when the capacitance of the first sensing clock line 121 increases.

Referring to FIG. 5, a display apparatus 100'' may have different arrangement of an insulating pattern portion 140'' from that of FIG. 2. In an embodiment, the insulating pattern portion 140'' may be disposed to overlap the first to sixth sensing clock signals 121 to 126 of the sensing clock line portion 120, for example.

Because the first to sixth sensing clock lines 121 to 126 overlap the insulating pattern portion 140'', inconsistent luminance increase due to the variation in the capacitance of the first to sixth scan clock lines 111 to 116 caused by the vertical isolation due to the external environment may be reduced or prevented to reduce visibility of the luminance defects. As such, the image quality characteristic of the display apparatus may be improved. In some embodiments, the first scan clock line 111 is the line of the scan clock line portion 110, which is closest to the insulating pattern portion 140'', and thus, the range of luminance increase may be reduced and the image quality characteristics may be improved.

The display apparatus 100 of the embodiment includes the circuit region disposed in the peripheral area PA for driving the scan signals, in detail, may include the scan clock line portion 110, the sensing clock line portion 120, and the stage portion 130. In some embodiments, the display apparatus 100 may include the insulating pattern portion 140 overlapping the scan clock line portion 110 or the sensing clock line portion 120.

The stage portion 130 includes the plurality of stages 131, 132, and 136, and the plurality of lines of the scan clock line portion and the lines of the sensing clock line portion may be sequentially connected to each of the stages. Here, the scan clock line portion and the sensing clock line portion are arranged in one direction, and the plurality of lines included in each of the scan and sensing clock line portions may be arranged in one direction. In some embodiments, the plurality of scan clock lines of the scan clock line portion are arranged sequentially in one direction, that is, arranged sequentially in one direction in an order of sixth to first scan clock lines, and the plurality of sensing clock lines of the sensing clock line portion may be sequentially arranged in one direction in the opposite order, that is, arranged in one direction in the order of first to sixth sensing clock lines.

When the vertical isolation occurs due to the moisture that is increased according to external or internal environment, and other usage time duration, the capacitance may change, e.g., may increase in the scan clock lines or the sensing clock lines, and accordingly, the luminance may increase or decrease in at least one region of the display apparatus 100. Here, the order of arranging the plurality of sensing clock lines and the order of arranging the plurality of scan clock lines are opposite to each other, for example, the lines are symmetrical with each other, and thus, a luminance increasing region and a luminance decreasing region are prevented from approaching each other due to the regions next (adjacent) to each other, e.g., the sixth scan clock line and the first sensing clock line next (adjacent) to each other, and the visibility of the inconsistent luminance variation may be reduced.

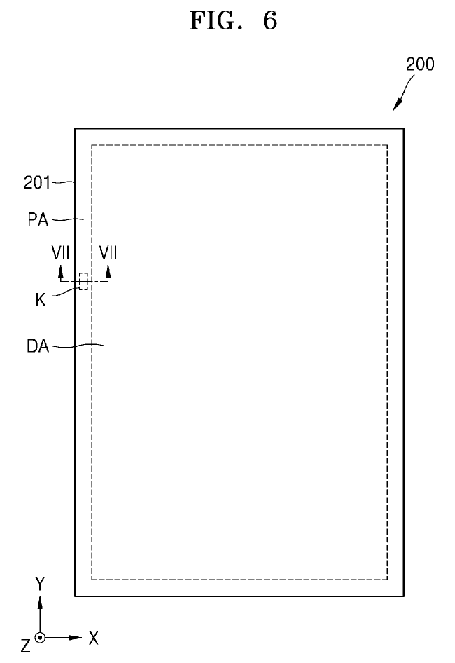

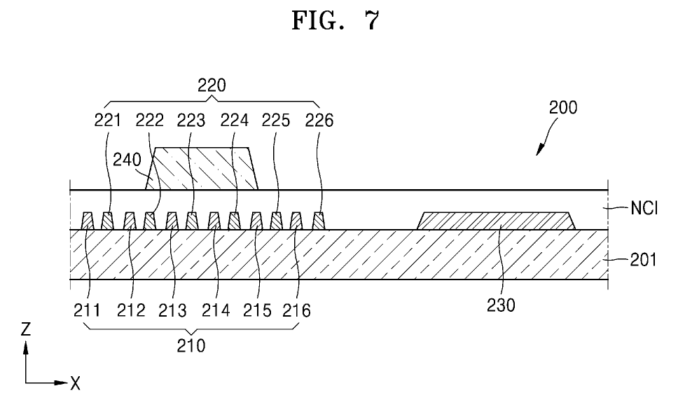

FIG. 6 is a plan view of another embodiment of a display apparatus according to the disclosure. FIG. 7 is a schematic cross-sectional view of region K taken along line VII-VII of FIG. 6.

A display apparatus 200 may include a substrate 201, a scan clock line portion 210, a sensing clock line portion 220, a stage portion 230, and an insulating pattern portion 240.

Referring to FIG. 6, the display apparatus 200 may include a display area DA and a peripheral area PA. Hereinafter, differences from the above-described embodiments are described in detail for convenience of description.

The scan clock line portion 210 may include a plurality of scan clock lines, e.g., first to sixth scan clock lines 211 to 216. The number of six is an example, and the number may be less than or greater than six.

The sensing clock line portion 220 may include a plurality of sensing clock lines, e.g., first to sixth sensing clock lines 221 to 226. The number of six is an example, and the number may be less than or greater than six.

The scan clock line portion 210 and the sensing clock line portion 220 may be arranged in one direction (e.g., X-axis direction), and in detail, the scan clock line portion 210 and the sensing clock line portion 220 may be spaced apart from each other in a width direction of each line portion and may be arranged in one direction (e.g., X-axis direction).

Each of the first to sixth sensing clock lines 221 to 226 of the sensing clock line portion 220 may be arranged in one direction. In an embodiment, the first to sixth sensing clock lines 221 to 226 may be sequentially arranged based on one direction (positive direction in X-axis or a direction from left to right based on FIG. 7), for example.

In other words, the first sensing clock line 221, the second sensing clock line 222, the third sensing clock line 223, the fourth sensing clock line 224, the fifth sensing clock line 225, and the sixth sensing clock line 226 may be sequentially arranged while being spaced apart from each other based on one direction (the positive direction in X-axis or the direction from left to right based on FIG. 7).

Each of the first to sixth scan clock lines 211 to 216 of the scan clock line portion 210 may be arranged in one direction. In an embodiment, the first to sixth scan clock lines 211 to 216 may be sequentially arranged based on one direction (positive direction in X-axis or a direction from left to right based on FIG. 7), for example.

In other words, the first scan clock line 211, the second scan clock line 212, the third scan clock line 213, the fourth scan clock line 214, the fifth scan clock line 215, and the sixth scan clock line 216 may be sequentially arranged while being spaced apart from each other based on one direction (the negative direction in X-axis or the direction from left to right based on FIG. 7).

In some embodiments, each of the first to sixth sensing clock lines 221 to 226 of the sensing clock line portion 220 and each of the first to sixth scan clock lines 211 to 216 of the scan clock line portion 210 may be arranged to be next (adjacent) to each other.

In other words, one sensing clock line may be disposed between two scan clock lines next (adjacent) to each other, and one scan clock line may be disposed between the two sensing clock lines next (adjacent) to each other.

In other words, each of the first to sixth sensing clock lines 221 to 226 of the sensing clock line portion 220 and each of the first to sixth scan clock lines 211 to 216 of the scan clock line portion 210 may be sequentially arranged alternately with each other.

In other words, in one direction (e.g., a positive direction in X-axis in FIG. 7, and a direction from left to right based on FIG. 7), for example, a direction in which the scan clock line portion 210 and the sensing clock line portion 220 are arranged, the first scan clock line 211, the first sensing clock line 221, the second scan clock line 212, the second sensing clock line 222, the third scan clock line 213, the third sensing clock line 223, the fourth scan clock line 214, the fourth sensing clock line 224, the fifth scan clock line 215, the fifth sensing clock line 225, the sixth scan clock line 216, and the sixth sensing clock line 226 may be sequentially arranged.

In another alternative embodiment, the first sensing clock line 221, instead of the first scan clock line 211, may be disposed first.

In some embodiments, in another alternative embodiment, in a direction opposite to the above direction (e.g., negative direction in the X-axis in FIG. 7, the direction from right to left of FIG. 7), each of the first to sixth sensing clock lines 221 to 226 of the sensing clock line portion 220 and each of the first to sixth scan clock lines 211 to 216 of the scan clock line portion 210 may be sequentially arranged alternately with each other.

The stage portion 230 may be disposed to be spaced apart from the scan clock line portion 210 and the sensing clock line portion 220, and may be connected via one or more connection lines. Although not shown in the drawings, the stage portion 230 may include a plurality of stages, e.g., six stages, and each of the plurality of stages may output a scan signal to a scan signal line and a sensing signal to a sensing signal line.

The stages included in the stage portion 230 may be respectively connected to the lines of the scan clock line portion 210 and the lines of the sensing clock line portion 220. In an embodiment, the first scan clock line 211 of the scan clock line portion 210 and the first sensing clock line 221 of the sensing clock line portion 220 may be electrically connected to the first stage (not shown) respectively via conductive connection lines, for example. In some embodiments, the second scan clock line 212 of the scan clock line portion 210 and the second sensing clock line 222 of the sensing clock line portion 220 may be electrically connected to the second stage (not shown) respectively via conductive connection lines. In this manner, the scan clock line and the sensing clock line may be electrically connected to a corresponding one (e.g., stage of the same number) of the plurality of stages of the stage portion 230.

The insulating pattern portion 240 may be disposed to overlap with at least a region of the scan clock line portion 210 or the sensing clock line portion 220.

In an alternative embodiment, the insulating layer NCI may be formed on the scan clock line portion 210 and the sensing clock line portion 220, and the insulating pattern portion 240 may be insulated from the scan clock line portion 210 and the sensing clock line portion 220 by the insulating layer NCI.

In an alternative embodiment, the insulating layer NCI may be formed on the stage portion 230 to cover the stage portion 230.

In an alternative embodiment, another insulating layer may be formed on the insulating layer NCI so as to correspond to at least one side surface or the upper surface of the insulating pattern portion 240.

The insulating pattern portion 240 may be disposed to overlap with at least a region of the scan clock line portion 210 or the sensing clock line portion 220.

Referring to FIG. 7, the insulating pattern portion 240 may be disposed to overlap the third and fourth scan clock lines 213 and 214 of the scan clock line portion 210 and the third and fourth sensing clock lines 223 and 224 of the sensing clock line portion 220, and at least a part of the second sensing clock line 222 and at least a part of the fifth scan clock line 215.

A direction in which the first to sixth scan clock lines 211 to 216 of the scan clock line portion 210 are sequentially arranged is the same as that of the first to sixth sensing clock lines 221 to 226 of the sensing clock line portion 220.

In some embodiments, one sensing clock line may be disposed between two scan clock lines next (adjacent) to each other, one scan clock line may be disposed between two sensing clock lines next (adjacent) to each other, for example, each of the first to sixth sensing clock lines 221 to 226 of the sensing clock line portion 220 and each of the first to sixth scan clock lines 211 to 216 of the scan clock line portion 210 may be sequentially arranged alternately with each other.

As such, a variation in image quality characteristic (e.g., increase in luminance) through the first to sixth scan clock lines 211 to 216 of the scan clock line portion 210 and a variation in image quality characteristic (e.g., decrease in luminance) through the first to sixth sensing clock lines 221 to 226 of the sensing clock line portion 220 offset each other, and thus, defects of inconsistent luminance due to external and internal environmental issues in use of the display apparatus 200 may be reduced.

In some embodiments, when the display apparatus 200 is used in an environment of relatively high temperature and relatively high humidity, moisture may infiltrate through the edges, and the insulating pattern portion 240 is closer to the edge of the display apparatus 200, rather than the center, and thus, vertical isolation may occur in the region next (adjacent) to the insulating pattern portion 240. Due to the vertical isolation, the capacitance may change in the region next (adjacent) to the insulating pattern portion 240, and in detail, the capacitance of the scan clock line portion 210 or the sensing clock line portion 220 may increase.

In some embodiments, in an illustrative embodiment, when the capacitance increases in the region next (adjacent) to each clock line of the scan clock line portion 210, a voltage applied to a gate of a transistor that drives pixels via the scan signal lines increases, and accordingly, the luminance of the display device may increase. In some embodiments, in another detailed example, when the capacitance increases in a region next (adjacent) to each clock line of the sensing clock line portion 220, a voltage applied to a gate of a transistor related to initialization of connected pixels increases, and accordingly, the luminance of the display device may decrease.

In some embodiments, the increase or decrease in the luminance of the clock lines may vary depending on the order, for example, the luminance may increase according to the order of the first to sixth scan clock lines 211 to 216 of the scan clock line portion 210. In some embodiments, the luminance may decrease according to the order of the first to sixth sensing clock lines 221 to 226 of the sensing clock line portion 220.

In an embodiment, each of the first to sixth sensing clock lines 221 to 226 of the sensing clock line portion 220 and each of the first to sixth scan clock lines 211 to 216 of the scan clock line portion 210 may be sequentially arranged alternately with each other, for example, the first scan clock line 211 and the first sensing clock line 221 are next (adjacent) to each other, and the second scan clock line 212 and the second sensing clock line 222 are next (adjacent) to each other, and so on. Thus, the luminance increase and the luminance decrease may easily offset each other, and as such, the visibility of the inconsistent image quality due to the inconsistent luminance may be reduced and the image quality characteristics of the display apparatus 200 may be improved.

In some embodiments, in FIG. 7, the insulating pattern portion 240 may be disposed in a region including the center along the width direction of the scan clock line portion 210 and the sensing clock line portion 220, and as such, generation of rapid luminance variation in the first or sixth scan clock line or the first or sixth sensing clock line may be reduced.

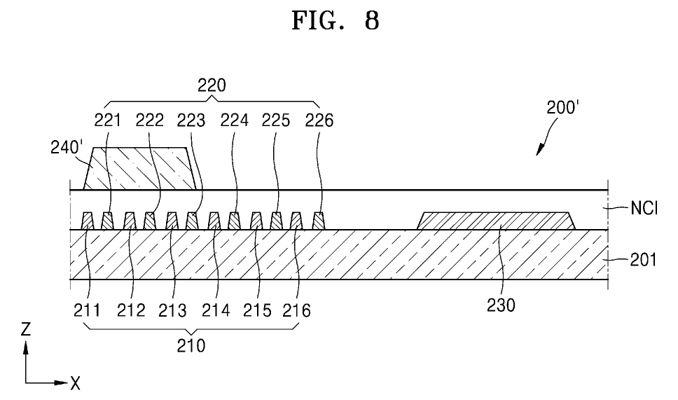

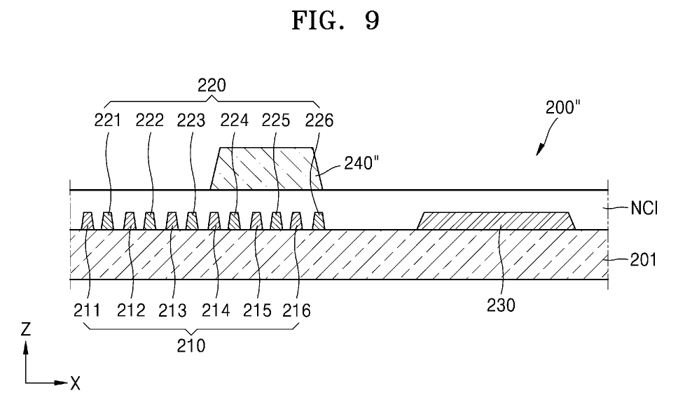

FIGS. 8 and 9 are schematic cross-sectional views showing a modified embodiment of the configuration shown in FIG. 7.

Referring to FIG. 8, a display apparatus 200' may have different arrangement of an insulating pattern portion 240' from that of FIG. 7. In an embodiment, the insulating pattern portion 240' may be disposed to overlap the first scan clock line 211, the first sensing clock line 221, the second scan clock line 212, the second sensing clock line 222, the third scan clock line 213, and the third sensing clock line 223, for example.

Pairs of the scan clock lines and the sensing clock lines (e.g., three pairs) connected to the same stage overlap the insulating pattern portion 240', and thus, inconsistency in the luminance increase or luminance decrease caused by the capacitance increase that is generated due to the isolation between upper and lower layers according to the external environment may be precisely controlled.

Referring to FIG. 9, a display apparatus 200'' is different from that of FIG. 7 in view of the arrangement of an insulating pattern portion 240''. In an embodiment, the insulating pattern portion 240'' may be disposed to overlap the fourth scan clock line 214, the fourth sensing clock line 224, the fifth scan clock line 215, the fifth sensing clock line 225, the sixth scan clock line 216, and the sixth sensing clock line 226, for example.

Pairs of the scan clock lines and the sensing clock lines (e.g., three pairs) connected to the same stage overlap the insulating pattern portion 240”, and thus, unevenness in the luminance increase or luminance decrease caused by the capacitance increase that is generated due to the isolation between upper and lower layers according to the external environment may be precisely controlled.

The display apparatus 200 of the embodiment includes the circuit region disposed in the peripheral area PA for driving the scan signals, in detail, may include the scan clock line portion 210, the sensing clock line portion 220, and the stage portion 230. In some embodiments, the display apparatus 200 may include the insulating pattern portion 240 overlapping the scan clock line portion 210 or the sensing clock line portion 220.

The stage portion 230 includes a plurality of stages, and the plurality of lines of the scan clock line portion and the lines of the sensing clock line portion may be sequentially connected to each of the stages. Here, the scan clock line portion and the sensing clock line portion are arranged in one direction, and the plurality of lines included in each of the scan and sensing clock line portions may be arranged in one direction. In some embodiments, the plurality of scan clock lines of the scan clock line portion and the plurality of sensing clock lines of the sensing clock line portion may be sequentially arranged alternately with each other.

As such, the luminance increase region and the luminance decrease region in the display apparatus may be easily offset each other, and the visibility of the inconsistent variation in the luminance may be reduced.

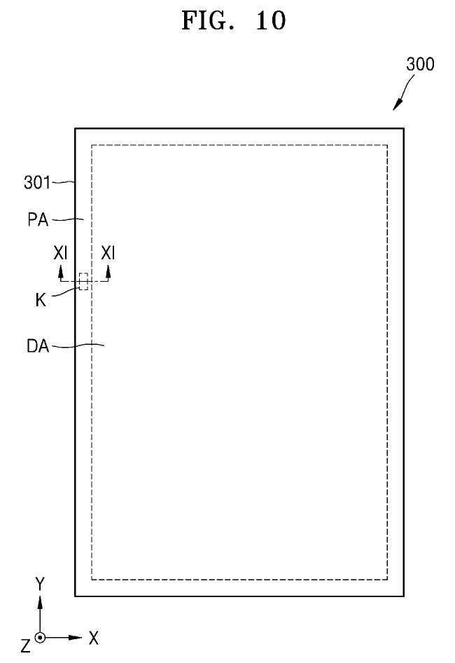

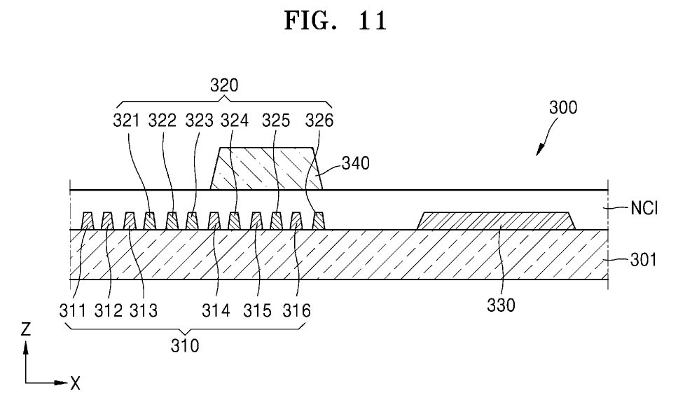

FIG. 10 is a schematic plan view of another embodiment of a display apparatus according to the disclosure. FIG. 11 is a schematic cross-sectional view of region K taken along line XI-XI of FIG. 10.

A display apparatus 300 may include a substrate 301, a scan clock line portion 310, a sensing clock line portion 320, a stage portion 330, and an insulating pattern portion 340.

Referring to FIG. 10, the display apparatus 300 may include the display area DA and the peripheral area PA. Hereinafter, differences from the above-described embodiments are described below for convenience of description.

The scan clock line portion 310 may include a plurality of scan clock lines, e.g., first to sixth scan clock lines 311 to 316.

The sensing clock line portion 320 may include a plurality of sensing clock lines, e.g., first to sixth sensing clock lines 321 to 326.

The scan clock line portion 310 and the sensing clock line portion 320 may be arranged in one direction (e.g., X-axis direction), and in detail, the scan clock line portion 310 and the sensing clock line portion 320 may be spaced apart from each other in a width direction of each line portion and may be arranged in one direction (e.g., X-axis direction).

Each of the first to sixth sensing clock lines 321 to 326 of the sensing clock line portion 320 may be arranged in one direction. In an embodiment, the first to sixth sensing clock lines 321 to 326 may be sequentially arranged based on one direction (positive direction in X-axis or a direction from left to right based on FIG. 11), for example.

Each of the first to sixth scan clock lines 311 to 316 of the scan clock line portion 310 may be arranged in one direction. In an embodiment, the first to sixth scan clock lines 311 to 316 may be sequentially arranged based on one direction (positive direction in X-axis or a direction from left to right based on FIG. 11), for example.

In some embodiments, each of the first to sixth sensing clock lines 321 to 326 of the sensing clock line portion 320 and each of the first to sixth scan clock lines 311 to 316 of the scan clock line portion 310 may be disposed to be next (adjacent) to each other in at least the region overlapping the insulating pattern portion 340.

In other words, in the region overlapping the insulating pattern portion 340, one sensing clock line may be disposed between two scan clock lines next (adjacent) to each other, and one scan clock line may be disposed between two sensing clock lines next (adjacent) to each other.

In other words, in the region overlapping the insulating pattern portion 340, each of the first to sixth sensing clock lines 321 to 326 of the sensing clock line portion 320 and each of the first to sixth scan clock lines 311 to 316 of the scan clock line portion 310 may be sequentially arranged alternately with each other.

In other words, in one direction (e.g., positive direction in the X-axis of FIG. 11, a direction from left to right in FIG. 11), for example, the first scan clock line 311, the second scan clock line 312, and the third scan clock line 313 of the scan clock line portion 310 are arranged, and in the same direction, the first sensing clock line 321, the second sensing clock line 322, and the third sensing clock line 323 may be arranged.

In some embodiments, in the region overlapping the insulating pattern portion 340, the fourth scan clock line 314, the fourth sensing clock line 324, the fifth scan clock line 315, the fifth sensing clock line 325, the sixth scan clock line 316, and the sixth sensing clock line 326 may be arranged.

In an embodiment, in the region overlapping the insulating pattern portion, one sensing clock line may be disposed between two scan clock lines next (adjacent) to each other, and one scan clock line may be disposed between two sensing clock lines next (adjacent) to each other. As such, the inconsistency in the luminance increase or luminance decrease may be offset, and the defects of inconsistent luminance in the display apparatus may be reduced.

As such, the visibility of the inconsistent image quality due to the inconsistent luminance may be reduced, and the image quality characteristics of the display apparatus 300 may be improved.

In the drawing, the insulating pattern portion 340 is shown to be biased toward the right side, but the insulating pattern portion 340 may be disposed at the center or biased toward the left side.

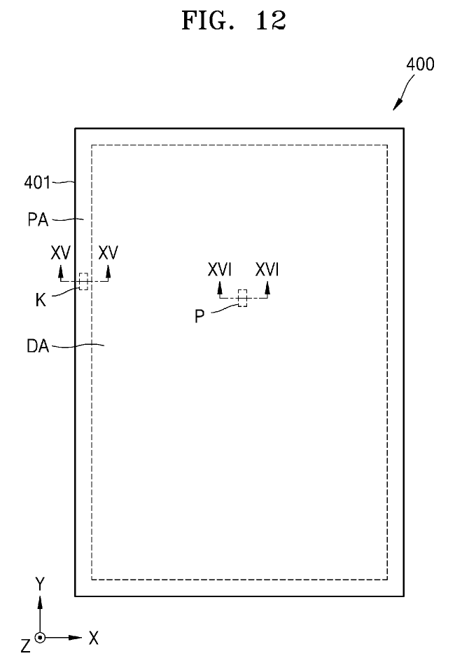

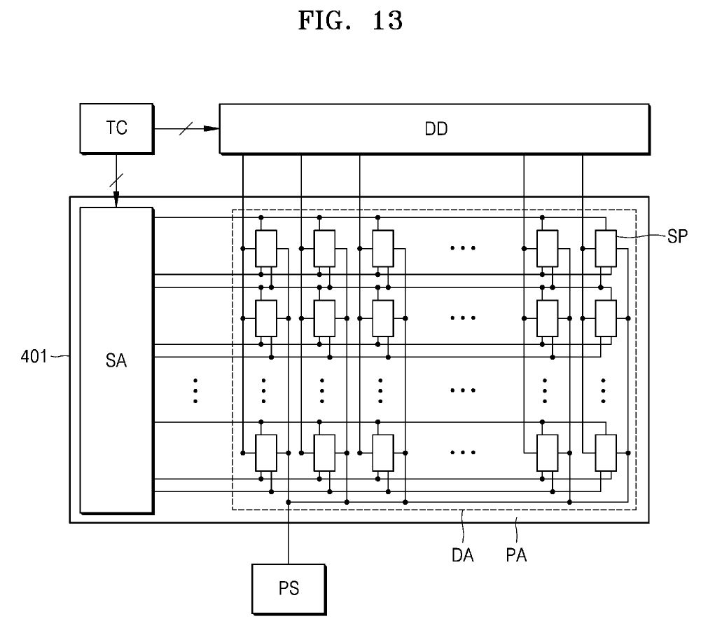

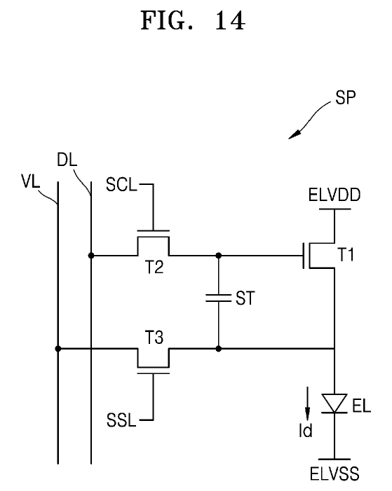

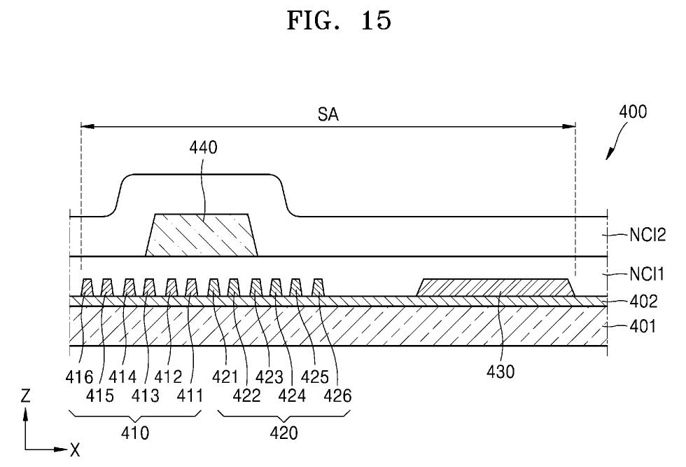

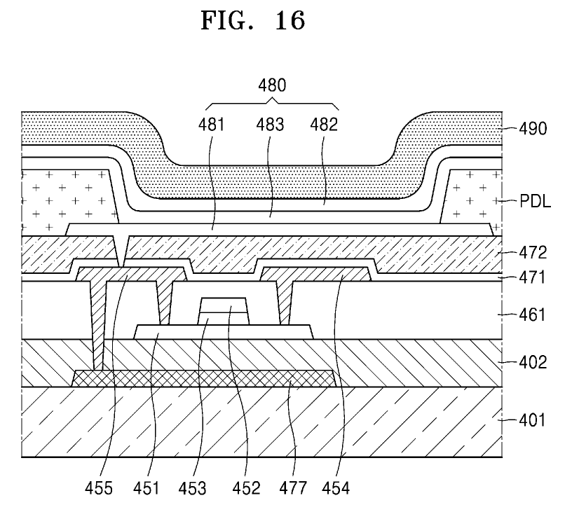

FIG. 12 is a schematic plan view of another embodiment of a display apparatus according to the disclosure. FIG. 13 is a block diagram of a display apparatus of FIG. 12. FIG. 14 is a circuit diagram schematically showing one sub-pixel in the display apparatus of FIG. 12. FIG. 15 is a schematic cross-sectional view of region K taken along line XV-XV of FIG. 12. FIG. 16 is a schematic cross-sectional view taken along line XVI-XVI of FIG. 12.

The display apparatus 400 may include the display area DA and the peripheral area PA.

The display area DA may include one or more display devices (e.g., 480 of FIG. 16), e.g., organic light-emitting devices, so as to display images. In another embodiments, the display device may include one of a quantum dot light-emitting device, a liquid crystal display device, and other various kinds of display devices. In an embodiment, the display device being an organic light-emitting device is described, but other kinds of display devices may be also applied.

In some embodiments, a plurality of pixels (e.g., SP in FIG. 13) may be disposed in the display area DA, and one or more display devices may be disposed in each pixel.

The peripheral area PA may be formed around the display area DA. The peripheral area PA may include a non-display area, for example, the non-display area may be formed to surround the display area DA. In some embodiments, in another alternative embodiment, the peripheral area PA or the non-display area in the peripheral area PA may be next (adjacent) to only one side or opposite side surfaces of the display area DA.

A drive circuit region generating various signals for operating pixels in the display area DA may be disposed in the peripheral area PA, and the drive circuit region may include one or more drive circuit portions.

FIG. 13 is a block diagram schematically showing the display apparatus of FIG. 12, and referring to FIGS. 12 to 14, the display apparatus is schematically described below.

In the display area DA, not only the sub-pixels SP, but the scan signal lines SCL, the sensing signal lines SSL, data lines DL, and a first driving voltage line connected to the sub-pixels may be also disposed. The scan signal lines SCL and the sensing signal lines SSL may extend in the first direction (e.g., X-axis direction) in the display area DA. The data lines DL may extend in a second direction (e.g., Y-axis direction) crossing the first direction (e.g., X-axis direction) in the display area DA. The first driving voltage line may extend in, for example, the second direction (Y-axis direction) in the display area DA.

Each of the sub-pixels SP may be connected to one of the scan signal lines SCL, one of the data lines DL, and one of the sensing signal lines SSL. FIG. 13 shows an example, in which each of the sub-pixels SP is connected to one scan signal line SCL, one data line DL, and one sensing signal line SSL, but is not limited thereto.

The sub-pixels SP may be connected to the first driving voltage line in common.

In some embodiments, each of the sub-pixels SP may include a driving transistor, at least one transistor, a display device, and a capacitor. The transistor is turned on when a scan signal is applied from the scan signal line SCL, and accordingly, a data voltage of the data line DL may be applied to a gate electrode of a first transistor T1. The first transistor T1 may emit light by supplying a driving current Id to the light-emitting device according to the data voltage applied to the gate electrode. The first transistor T1 and at least one switching transistor may include thin film transistors. The display device, e.g., the organic light-emitting device (e.g., 480 of FIG. 16) may emit light according to the driving current Id of the first transistor T1.

The capacitor may constantly maintain the data voltage applied to the gate electrode of the first transistor T1.

A scan signal driver SA may be disposed in the peripheral area PA. The scan signal driver SA may apply scan signals to the scan signal lines SCL and sensing signals to the sensing signal lines SSL.

In an embodiment, the scan signal driver SA may receive an input of a scan control signal from a timing controller TC, for example. The scan control signal may include a plurality of clock signals, a sensing control signal, a gate-on voltage, and a gate-off voltage.

The scan signal driver SA may output the scan signals and the sensing signals to the scan signal lines SCL and the sensing signal lines SSL.

FIG. 13 shows an embodiment in which the scan signal driver SA is formed on one side of the display area DA, e.g., in the peripheral area PA at the left side of the display area DA, but is not limited thereto. In an embodiment, the scan signal driver SA may be disposed on one side or opposite sides of the display area DA, for example.

The timing controller TC may be separately disposed and coupled to the display apparatus 400, and in another embodiment, the timing controller TC may be unitary with the display apparatus 400. The timing controller TC may include an integrated circuit, for example, may receive inputs of digital video data and timing signals from a system-on-chip of a system circuit board. The timing controller TC may generate a control signal for controlling a data driver DD and a scan control signal for controlling the timing of the scan signal driver SA according to the timing signals. In an alternative embodiment, the timing controller TC may output a scan control signal to the scan signal driver SA and digital video data and a source control signal to the data driver DD.

A power supplier PS may be separately disposed and coupled to the display apparatus 400, and in another embodiment, may be unitary with the display apparatus 400. The power supplier PS may generate the first driving voltage and supply the first driving voltage to the first driving voltage line. In some embodiments, the power supplier PS may generate and supply a second driving voltage to a cathode electrode of the display device in each of the sub-pixels SP. In an alternative embodiment, the power supplier PS may generate and supply a reference voltage to a reference voltage line connected to each of the sub-pixels SP.

FIG. 14 is a circuit diagram schematically showing one sub-pixel in the display apparatus of FIG. 12.

Referring to FIG. 14, the sub-pixel SP may include a light-emitting device EL, a first transistor T1, a second transistor T2, a third transistor T3, and a capacitor ST.

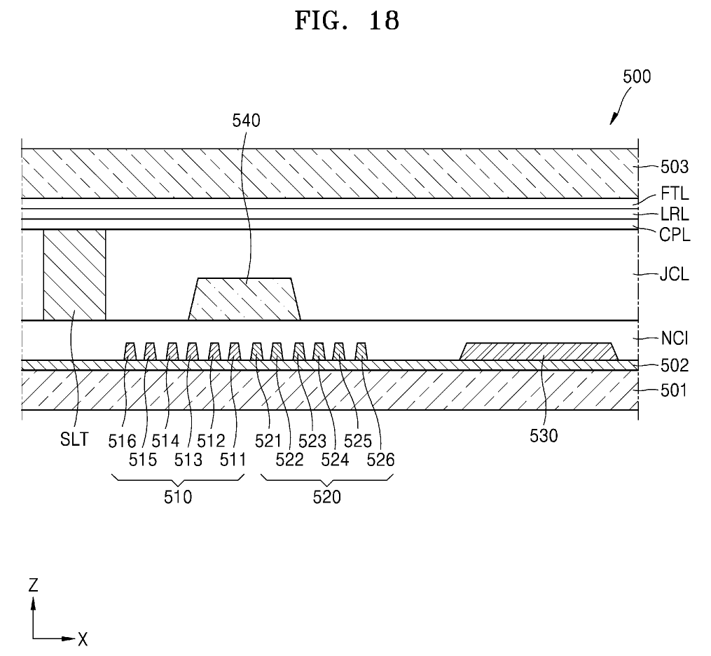

The light-emitting device EL may emit light according to a driving current Id supplied via the first transistor T1. The light-emitting device EL may be an organic light-emitting device (e.g., 480 of FIG. 16), but is not limited thereto. In an embodiment, the light-emitting device EL may include a quantum dot light-emitting diode, an inorganic light-emitting diode, or an ultra-small size light-emitting diode, for example. A detailed description of an embodiment in which the light-emitting device EL is an organic light-emitting device (480 of FIG. 16) is provided later with reference to FIG. 18.

In an embodiment, a pixel electrode of the light-emitting device EL is connected to one connection electrode of the first transistor T1, and an opposite electrode facing the pixel electrode may be connected to a second driving voltage line ELVSS.

The first transistor T1 may adjust the current flowing from the first power line ELVDD to which a first power voltage is supplied to the light-emitting device EL according to a voltage difference between the gate electrode and one connection electrode. The gate electrode of the first transistor T1 is connected to one connection electrode of the second transistor T2, one connection electrode of the first transistor T1 is connected to the pixel electrode of the light-emitting device EL, and another connection electrode of the first transistor T1 may be connected to the first power line ELVDD.

The second transistor T2 may be turned on by the scan signal of the scan signal line SCL and may connect the data line DL to the gate electrode of the first transistor T1. The gate electrode of the second transistor T2 is connected to the scan signal line SCL, one connection electrode of the second transistor T2 may be connected to the gate electrode of the first transistor T1, and another connection electrode may be connected to the data line DL.

The third transistor T3 is turned on by the sensing signal of the sensing signal line SSL and may connect the reference voltage line VL to one connection electrode of the first transistor T1. The gate electrode of the third transistor T3 may be connected to the sensing signal line SSL, one connection electrode of the third transistor T3 may be connected to the reference voltage line VL, and another connection electrode may be connected to one connection electrode of the first transistor T1.

The capacitor Cst is formed between the gate electrode and one connection electrode of the first transistor T1. The capacitor Cst stores a voltage corresponding to a difference between the gate voltage and the connection electrode voltage of the first transistor T1.

The first to third transistors T1, T2, and T3 may include thin film transistors. The first to third transistors T1, T2, and T3 may include P-type transistors. In another embodiment, the first to third transistors T1, T2, and T3 may include N-type transistors.

FIG. 15 is a schematic cross-sectional view of region K taken along line XV-XV of FIG. 12.

Referring to FIG. 15, the display apparatus 400 may include a substrate 401, a scan clock line portion 410, a sensing clock line portion 420, a stage portion 430, and an insulating pattern portion 440.

The scan clock line portion 410, the sensing clock line portion 420, and the stage portion 430 may be included in the scan signal driver SA.

The substrate 401 may be the same as the above description or may be modified within a similar range, and detailed descriptions thereof are omitted.

In an alternative embodiment, one or more buffer layers 402 may be arranged between the substrate 401 and the scan signal driver SA.

The buffer layer 402 may be disposed on the substrate 401. The buffer layer 402 may reduce or prevent impurities from infiltrating or dispersing through the substrate 401.

The buffer layer 402 may include various materials, e.g., an inorganic material. In an illustrative embodiment, a silicon-based material may be included. In an alternative embodiment, the buffer layer 402 may include at least one of silicon nitride (SiNx), silicon oxide (SiOx), and silicon oxynitride (SiOxNy).

In another embodiment, the buffer layer 402 may include an oxide material, in more detail, at least one of metal oxides such as aluminum oxide (AlOx).

In an alternative embodiment, the buffer layer 402 may include multiple layers, e.g., at least dual layers.

The scan clock line portion 410 may include a plurality of scan clock lines, e.g., first to sixth scan clock lines 411 to 416.

The sensing clock line portion 420 may include a plurality of sensing clock lines, e.g., first to sixth sensing clock lines 421 to 426.

The scan clock line portion 410 and the sensing clock line portion 420 may be arranged in one direction (e.g., X-axis direction), and in detail, the scan clock line portion 410 and the sensing clock line portion 420 may be spaced apart from each other in a width direction of each line portion and may be arranged in one direction (e.g., X-axis direction).

The arrangement of the first to sixth sensing clock lines 421 to 426 of the sensing clock line portion 420 and the arrangement of the first to sixth scan clock lines 411 to 416 of the scan clock line portion in detail are the same as the previous embodiment, e.g., the embodiment shown in FIG. 2, and thus, detailed descriptions thereof are omitted.

The stage portion 430 may be disposed to be spaced apart from the scan clock line portion 410 and the sensing clock line portion 420, and may be connected via one or more connection lines.

In an embodiment, the stage portion 430, the scan clock line portion 410, and the sensing clock line portion 420 may be arranged in one direction (X-axis direction), in more detail, as shown in the drawings, the stage portion 430 may be disposed to face one side of opposite sides of the sensing clock line portion 420, which does not face the scan clock line portion 410, for example. This is an illustrative embodiment, and the stage portion 430 may be disposed on at least one side of the scan clock line portion 410 or the sensing clock line portion 420.

Although not shown in the drawings, the stage portion 430 may include a plurality of stages, e.g., six stages (refer to FIG. 3 as an illustrative embodiment).

Although not shown in the drawings, in an alternative embodiment, the scan signal driver SA may further include one or more clock line portions, for example, a carry clock line portion and a global clock line portion may be included, each of which includes a plurality of clock lines. The plurality of clock lines may be respectively connected to the plurality of stages of the stage portion 430.

Each of the plurality of stages in the stage portion 430 may be connected to at least one scan signal line SCL to apply scan signals, and may be connected to a sensing signal line SSL to apply sensing signals.

The insulating pattern portion 440 may be disposed to overlap with at least a region of the scan clock line portion 410 or the sensing clock line portion 420.

In an alternative embodiment, a first insulating layer NCI1 may be formed on the scan clock line portion 410 and the sensing clock line portion 420, and the insulating pattern portion 440 may be insulated from the scan clock line portion 410 and the sensing clock line portion 420 by the first insulating layer NCI1.

In an alternative embodiment, the first insulating layer NCI1 may be formed on the stage portion 430 to cover the stage portion 430.

In an alternative embodiment, a second insulating layer NCI2 may be formed on the first insulating layer NCI1. In an embodiment, the second insulating layer NCI2 may be formed to contact the insulating pattern portion 440, and in detail, may be formed to correspond to one side surface or upper surface of the insulating pattern portion 440. In an alternative embodiment, the second insulating layer NCI2 may be formed to cover the insulating pattern portion 440.

The insulating pattern portion 440 may be disposed to overlap with at least a region of the scan clock line portion 410 or the sensing clock line portion 420.

The insulating pattern portion 440 may perform various functions, for example, may form a manufacturing device (e.g., mask member) for forming one or more layers in the display apparatus 400, and to this end, may be formed to have a set height. In another embodiment, the insulating pattern portion 440 may be used for another function, for example, may be a partition wall that restricts formation of next (adjacent) layers (e.g., insulating layer or encapsulation portion).

The insulating pattern portion 440 may include various insulating materials, e.g., an organic material. In some embodiments, the insulating pattern portion 440 may be formed to have a single layer or multi-layers.

Referring to FIG. 15, the insulating pattern portion 440 may be disposed to overlap the first to third scan clock lines 411 to 413 of the scan clock line portion 410 and the first to third sensing clock lines 421 to 423 of the sensing clock line portion 420.

Descriptions regarding the arrangement of the insulating pattern portion 440, the scan clock line portion 410, and the sensing clock line portion 420 are substantially the same as the above description provided with reference to the structure of FIG. 2, and thus, detailed descriptions thereof are omitted.

In an embodiment, a variation in image quality characteristic (e.g., increase in luminance) through the first to sixth scan clock lines 411 to 416 of the scan clock line portion 410 and a variation in image quality characteristic (e.g., decrease in luminance) through the first to sixth sensing clock lines 421 to 426 of the sensing clock line portion 420 offset each other, and thus, defects of inconsistent luminance due to external and internal environmental issues in use of the display apparatus 400 may be reduced.

In some embodiments, when the display apparatus 400 is used in an environment of relatively high temperature and relatively high humidity, moisture may infiltrate through the edges, and the insulating pattern portion 440 is closer to the edge of the display apparatus 400, rather than the center, and thus, vertical isolation may occur in the region next (adjacent) to the insulating pattern portion 440. Due to the vertical isolation, the capacitance may change in the region next (adjacent) to the insulating pattern portion 440, and in detail, the capacitance of the scan clock line portion 410 or the sensing clock line portion 420 may increase.

In some embodiments, in an illustrative embodiment, when the capacitance increases in the region next (adjacent) to each clock line of the scan clock line portion 410, a voltage applied to the gate of the first transistor T1 via the scan signal line increases, and accordingly, the luminance of the light-emitting device EL (refer to FIG. 14) may increase. In some embodiments, in another detailed example, when the capacitance increases in the region next (adjacent) to each clock line of the sensing clock line portion 420, a voltage applied to a gate of the third transistor T3 increases, and accordingly, the luminance of the light-emitting device EL (refer to FIG. 14) may decrease.

In some embodiments, the increase or decrease in the luminance of the clock lines may vary depending on the order, for example, the range of luminance increase may be increased according to the order of the first to sixth scan clock lines 411 to 416 of the scan clock line portion 410. In some embodiments, the range of luminance decrease may increase according to the order of the first to sixth sensing clock lines 421 to 426 of the sensing clock line portion 420. In this case, when the sixth scan clock line 416 and the first sensing clock line 421 are next (adjacent) to each other, the luminance variation increases and generation of image quality defects on the screen may increase. In an embodiment, the first to sixth scan clock lines 411 to 416 of the scan clock line portion 410 are sequentially arranged in one direction, and the first to sixth sensing clock lines 421 to 426 of the sensing clock line portion 420 may be disposed in opposite direction. Accordingly, the first scan clock line 411 and the first sensing clock line 421 may be disposed next (adjacent) to each other.

As a result, the increase in the luminance due to the increase in the capacitance of the first to sixth scan clock lines 411 to 416 of the scan clock line portion 410 and decrease in the luminance due to the increase in the capacitance of the first to sixth sensing clock lines 421 to 426 of the sensing clock line portion 420 may be reduced, and thus, luminance characteristics may be improved.

Although not shown in the drawings, in an alternative embodiment, one of the configurations of FIGS. 4 and 5 may be selectively applied.

FIG. 16 is a schematic cross-sectional view of region P taken along line XVI-XVI of FIG. 12. In an embodiment, FIG. 16 may show at least one region of one sub-pixel SP (refer to FIG. 13), for example.

The substrate 401 may include various materials. In some embodiments, the substrate 401 may include glass, metal, an organic material, or other materials. Descriptions regarding the substrate 401 are substantially the same as the detailed descriptions provided in the previous embodiment, and thus, detailed descriptions are omitted.

In an alternative embodiment, the buffer layer 402 may be disposed on the substrate 401.

One or more thin film transistors may be disposed on the substrate 401. The thin film transistor may include an active layer 451 and a gate electrode 452. In some embodiments, the thin film transistor may additionally include a first connection electrode 454 and a second connection electrode 455.

The active layer 451 may be disposed on the buffer layer 402.

In an embodiment, the active layer 451 may include a semiconductor material. In an embodiment, the active layer 451 may include a silicon-based semiconductor material, and in detail, may include polysilicon-based material. In another embodiment, the active layer 451 may include oxide semiconductor, for example.

The gate electrode 452 may be disposed to overlap the active layer 451, for example, may be disposed on the active layer 451 based on a thickness direction of the substrate 401.

A gate insulating layer 453 may be disposed to insulate the active layer 451 and the gate electrode 452 from each other. In an illustrative embodiment, the gate insulating layer 453 may be disposed on the active layer 451. The gate insulating layer 453 may include an insulating material, e.g., silicon oxide, silicon nitride, silicon oxynitride, etc., and may include one or a combination of the stated materials.

The gate electrode 452 may be disposed on the gate insulating layer 453 and may overlap the active layer 451. The gate electrode 452 may include a conductive material, e.g., metal, an alloy, conductive metal oxide, transparent conductive material, etc. In some embodiments, the gate electrode 452 may include a conductive material such as molybdenum (Mo), aluminum (Al), copper (Cu), titanium (Ti), argentum (Ag), tungsten (W), tungsten nitride (WN), nickel (Ni), chromium (Cr), chromium nitride (CrN), tantalum (Ta), platinum (Pt), scandium (Sc), indium-tin oxide (“ITO”), indium-zinc oxide (“IZO”), etc., and an alloy of the conductive materials. In some embodiments, the gate electrode 452 may include a single-layered or multi-layered structure including or consisting of the above stated materials.

An inter-insulating layer 461 may be disposed so as to insulate the gate electrode 452 from the first connection electrode 454 and the second connection electrode 455. In an embodiment, the inter-insulating layer 461 may be formed on the gate electrode 452 and the active layer 451 to cover the gate electrode 452 and the active layer 451, for example.

In some embodiments, the inter-insulating layer 461 may be disposed on the buffer layer 402. The inter-insulating layer 461 may include an insulating material.

The first connection electrode 454 and the second connection electrode 455 may be disposed on the inter-insulating layer 461. The first connection electrode 454 and the second connection electrode 455 may contact the active layer 451 respectively via contact holes in the inter-insulating layer 461.

Based on the signal applied to the gate electrode 452, the first connection electrode 454 and the second connection electrode 455 may be electrically connected to each other.

The first connection electrode 454 and the second connection electrode 455 may each include one of various conductive materials, e.g., metal, alloy, conductive metal oxide, a transparent conductive material, etc. In more detail, the first connection electrode 454 and the second connection electrode 455 may each include Ag, Mo, Al, AlN, tungsten (W), tungsten nitride (WN), Cu, Ni, Cr, CrN, Ti, Ta, Pt, Sc, ITO, IZO, etc.

In an alternative embodiment, a conductive pattern 477 may be further disposed.

In an embodiment, the conductive pattern 477 may have a region overlapping the active layer 451, and may be disposed between the substrate 401 and the buffer layer 402.

The conductive pattern 477 may reduce or block the light that may be incident on the substrate 401 and may be used as a light-shielding member for protecting the active layer 451 or a thin film transistor including the active layer 451. To this end, the conductive pattern 477 may include or consist of a light-shielding and/or light-absorbing material, for example, may include an opaque metal layer.

In an alternative embodiment, the conductive pattern 477 may be electrically connected to the first connection electrode 454 or the second connection electrode 455 via a contact hole sequentially penetrating through the inter-insulating layer 461 and the buffer layer 402. As such, various electrical control characteristics may be improved, for example, a driving range of a predetermined voltage supplied to the gate electrode 452 of the thin film transistor may be increased, and in another embodiment, a channel region of the active layer 451 may be stabilized.

In an alternative embodiment, the conductive pattern 477 may include various metals, e.g., may have a single layer including an appropriate (or selected) one or a combination from the group consisting of Cu, Mo, W, neodymium (Nd), Ti, Al, Ag, and any alloys thereof, or a dual or multi-layered structure including Mo, Ti, Cu, Al, or Ag that is a low-resistive material in order to reduce a line resistance.

One or more protective insulating layers 471 and 472 may be disposed on the inter-insulating layer 461. In an embodiment, a first protective insulating layer 471 may be disposed on the inter-insulating layer 461, and a second protective insulating layer 472 may be disposed on the first protective insulating layer 471, for example. The first protective insulating layer 471 and the second protective insulating layer 472 may include an insulating material. In an embodiment, the first and second protective insulating layers 471 and 472 may include various materials, e.g., one of or both an organic material and an inorganic material, and may include a single layer or multi-layers including an organic material, for example.

In more detail, the first protective insulating layer 471 may include an inorganic material, and the second protective insulating layer 472 may include an organic material.

In an alternative embodiment, the second protective insulating layer 472 may form a flat surface in at least one region, and as such, generation of defects in the display device 480 due to lower irregularities may be reduced or prevented.

The display device 480 may be disposed on the second protective insulating layer 472. As described above, the display device 480 may include one of various kinds, for example, may include an organic light-emitting device, and hereinafter, the organic light-emitting device is described as an example.

The display device 480 may include a first electrode 481, a second electrode 482, and an intermediate layer 483 interposed between the first and second electrodes 481 and 482.

The first electrode 481 may be connected to a lower circuit, e.g., a thin film transistor, and in detail, may be electrically connected to the second connection electrode 455 of the thin film transistor shown in FIG. 16.

The first electrode 481 may have various shapes, for example, may be patterned in an island shape.

The first electrode 481 may include various conductive materials. In an embodiment, the first electrode 481 may include at least one selected from the group consisting of transparent conductive oxides such as indium tin oxide (“ITO”), indium zinc oxide (“IZO”), zinc oxide (ZnO), indium oxide (In₂O₃), indium gallium oxide (“IGO”), and aluminum zinc oxide (“AZO”), for example. In some embodiments, the first electrode 481 may include metal having relatively high reflectivity such as Ag.

The intermediate layer 483 includes an organic emission layer, and the organic emission layer may include a low-molecular weight organic material or a high-molecular weight organic material. In an alternative embodiment, the intermediate layer 483 may further include at least one selected from the group consisting of a hole injection layer, a hole transport layer, an electron transport layer, and an electron injection layer, along with the organic emission layer.

In some embodiments, the organic emission layer may be separately formed for each organic light-emitting device. In this case, each of the organic light-emitting devices may emit red light, green light, or blue light. However, the disclosure is not limited thereto, and the organic emission layer may be commonly formed throughout the entirety of the organic light-emitting device. In an embodiment, a plurality of organic emission layers emitting red light, green light, and blue light may be vertically stacked or mixed to emit white light, for example. The combination of colors for emitting white light is not limited to the above example. In some embodiments, in this case, a color conversion layer for converting emitted white light into a predetermined color or a color filter may be separately provided.

The second electrode 482 may include various conductive materials. In an embodiment, the second electrode 482 may include lithium (Li), calcium (Ca), lithium fluoride (LiF), aluminum (Al), magnesium (Mg), or argentum (Ag), at least one of which is formed in a single layer or multiple layers, and may include an alloy material including at least two of the above materials, for example.

A pixel-defining layer PDL is disposed on the second protective insulating layer 472, and the pixel-defining layer PDL is disposed so as not to cover a predetermined region of the first electrode 481, and after that, the intermediate layer 483 is disposed on the region of the first electrode 481, which is not covered by the pixel-defining layer PDL, and the second electrode 482 may be disposed on the intermediate layer 483.

The pixel-defining layer PDL may include various insulating materials. In an embodiment, the pixel-defining layer PDL may include an organic material, in more detail, may include one or more organic insulating materials selected from the group consisting of polyimide, polyamide, acrylic resin, benzocyclobutene, and phenol resin and formed by a method such as spin coating, etc., for example.

In an alternative embodiment, a functional layer (not shown) having one or more layers may be further arranged on the second electrode 482, and in detail, at least one layer in the functional layer may reduce the contamination of the second electrode 482 during post-processes, and another layer of the functional layer may improve efficiency of visible ray emitted from the intermediate layer 483.

An encapsulation portion 490 may be disposed to protect the display device 480. In an embodiment, the encapsulation portion 490 including one or more encapsulation layers may be disposed on the second electrode 482 so as to block or reduce infiltration of moisture or other foreign substances into the display device 480, for example.

In an embodiment, the encapsulation portion 490 may include two or more, or four or more encapsulation layers. In an alternative embodiment, the encapsulation portion 490 may include one or more inorganic layers or one or more organic layers, and in an embodiment, the encapsulation portion may include a structure in which an inorganic layer and an organic layer are alternately stacked one or greater number of times, and in more detail, a structure in which the inorganic layer and the organic layer are alternately stacked multiple times.

In an alternative embodiment, the first insulating layer NCI1 described above may be formed simultaneously with the display area DA by the same material as each other. In an embodiment, the first insulating layer NCI1 may include the same material as that of the inter-insulating layer 461, for example.

In some embodiments, the insulating pattern portion 440 may be formed simultaneously with the insulating layer of the display area DA by the same material as each other. In an embodiment, the insulating pattern portion 440 may include the same material as the material included in at least one of the protective insulating layers 471 and 472 or the pixel-defining layer PDL, for example.

The display apparatus 400 of the embodiment may include the scan signal driver SA disposed in the peripheral area PA, and the scan signal driver may include the scan clock line portion 410, the sensing clock line portion 420, and the stage portion 430. In some embodiments, the display apparatus 400 may include the insulating pattern portion 440 overlapping the scan clock line portion 410 or the sensing clock line portion 420.

The stage portion includes a plurality of stages, and the plurality of lines of the scan clock line portion and the lines of the sensing clock line portion may be sequentially connected to each of the stages. Here, the scan clock line portion and the sensing clock line portion are arranged in one direction, and the plurality of lines included in each of the scan and sensing clock line portions may be arranged in one direction. In some embodiments, the plurality of scan clock lines of the scan clock line portion are arranged sequentially in one direction, that is, disposed sequentially in one direction in an order of sixth to first scan clock lines, and the plurality of sensing clock lines of the sensing clock line portion may be sequentially arranged in one direction in the opposite order, that is, arranged in one direction in the order of first to sixth sensing clock lines.

When the vertical isolation occurs due to the moisture that is increased according to external or internal environment, and other usage time duration, the capacitance may change, e.g., may increase in the scan clock lines or the sensing clock lines, and accordingly, the luminance may increase or decrease in at least one region of the display apparatus 400. Here, the order of arranging the plurality of sensing clock lines and the order of arranging the plurality of scan clock lines are opposite to each other, for example, the lines are symmetrical with each other, and thus, a luminance increasing region and a luminance decreasing region are prevented from approaching each other due to the regions next (adjacent) to each other, e.g., the sixth scan clock line and the first sensing clock line next (adjacent) to each other, and the visibility of the inconsistent luminance variation may be reduced.

Although not shown in the drawings, the configurations in FIGS. 6 to 11 described above may be selectively applied to the display apparatus 400 of the embodiment.

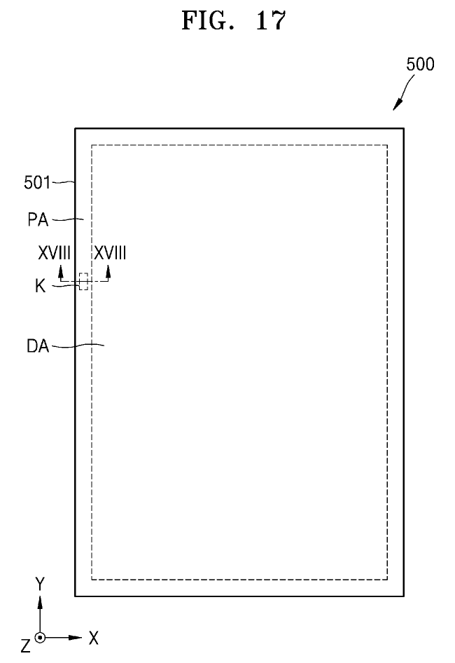

FIG. 17 is a schematic plan view of another embodiment of a display apparatus according to the disclosure. FIG. 18 is a schematic cross-sectional view of region K taken along line XVIII-XVIII of FIG. 17.

The display apparatus 500 may include a display area DA and a peripheral area PA. Hereinafter, differences from the display apparatus 400 of the previous embodiment are described in detail for convenience of description. Descriptions regarding a buffer layer 502, a scan clock line portion 510, a sensing clock line portion 520, a stage portion 530, and an insulating pattern portion 540 are omitted.

Referring to FIG. 18, the display apparatus 500 may further include an opposite substrate 503.

The opposite substrate 503 and the substrate 501 may be bonded to each other via a sealing member SLT, and a space generated due to the bonding may be filled with a filling material JCL.

A light conversion layer FTL may be disposed on one surface of the opposite substrate 503, e.g., a surface facing the substrate 501. The light conversion layer FTL is a layer for improving purity of light emitted from the display apparatus 500 and may include a color filter, for example.

In an alternative embodiment, a relatively low refractive index layer LRL may be disposed on the light conversion layer FTL. The relatively low refractive index layer LRL may include an organic material or an inorganic material having relatively low refractive index.

In an alternative embodiment, one or more capping layers CPL may be disposed on one surface of the relatively low refractive index layer LRL. The capping layer CPL may precisely control light characteristics or protect the relatively low refractive index layer LRL, and may include an inorganic insulating material.

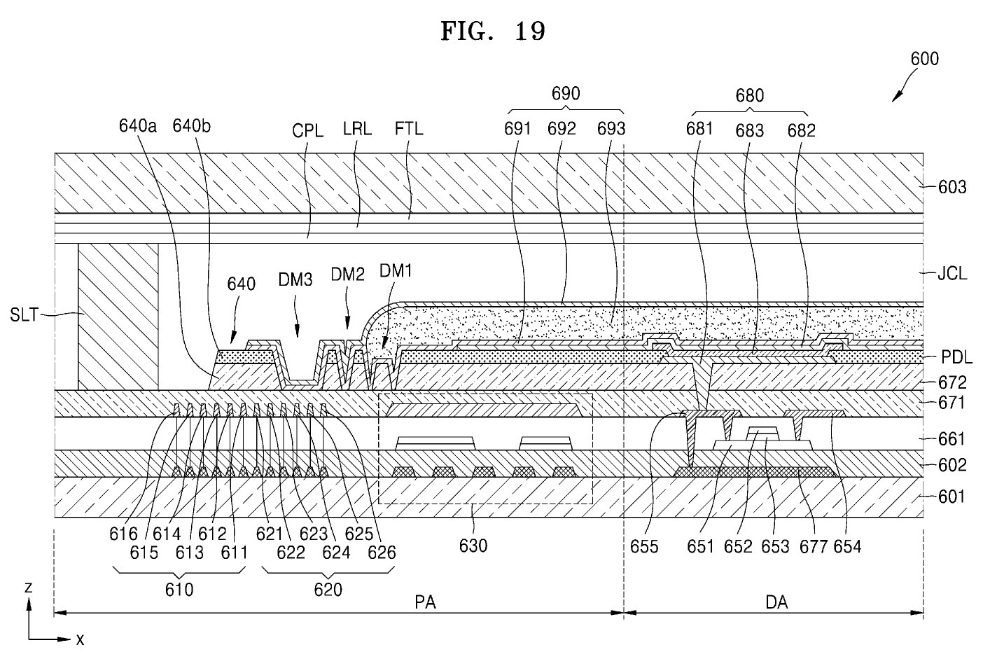

FIG. 19 is a schematic cross-sectional view of another embodiment of a display apparatus according to the disclosure.

Hereinafter, differences from the previously described embodiments are described in detail for convenience of description.

The display apparatus 600 may include the display area DA and the peripheral area PA.

In some embodiments, the display apparatus 600 may include a substrate 601, a scan clock line portion 610, a sensing clock line portion 620, a stage portion 630, and an insulating pattern portion 640.

In an alternative embodiment, a buffer layer 602 may be disposed on the substrate 601.

Referring to the display area DA, one or more thin film transistors may be disposed on the substrate 601. The thin film transistor may include an active layer 651 and a gate electrode 652. In some embodiments, the thin film transistor may additionally include a first connection electrode 654 and a second connection electrode 655.

In some embodiments, a gate insulating layer 653 may be disposed to insulate the active layer 651 and the gate electrode 652 from each other.

An inter-insulating layer 661 may be disposed so as to insulate the gate electrode 652 from the first connection electrode 654 and the second connection electrode 655. In an embodiment, the inter-insulating layer 661 may be formed on the gate electrode 652 and the active layer 651 to cover the gate electrode 652 and the active layer 651, for example.

The inter-insulating layer 661 may be disposed on the buffer layer 602.

The first connection electrode 654 and the second connection electrode 655 may be disposed on the inter-insulating layer 661. The first connection electrode 654 and the second connection electrode 655 may contact the active layer 651 respectively via contact holes in the inter-insulating layer 661.

Based on the signal applied to the gate electrode 652, the first connection electrode 654 and the second connection electrode 655 may be electrically connected to each other.

In an alternative embodiment, a conductive pattern 677 may be further disposed.

In an embodiment, the conductive pattern 677 may have a region overlapping the active layer 651, and may be disposed between the substrate 601 and the buffer layer 602.

One or more protective insulating layers 671 and 672 may be disposed on the inter-insulating layer 661. In an embodiment, a first protective insulating layer 671 may be disposed on the inter-insulating layer 661, and a second protective insulating layer 672 may be disposed on the first protective insulating layer 671, for example.

The display device 680 may be disposed on the second protective insulating layer 672. As described above, the display device 680 may include one of various kinds, for example, may include an organic light-emitting device, and hereinafter, the organic light-emitting device is described as an example.

The display device 680 may include a first electrode 681, a second electrode 682, and an intermediate layer 683 interposed between the first and second electrodes 681 and 682.

The first electrode 681 may be connected to a lower circuit, e.g., a thin film transistor, and in detail, may be electrically connected to the second connection electrode 655 of the thin film transistor.

The intermediate layer 683 includes an organic emission layer, and the organic emission layer may include a low-molecular weight organic material or a high-molecular weight organic material. In an alternative embodiment, the intermediate layer 683 may further include at least one selected from the group consisting of a hole injection layer, a hole transport layer, an electron transport layer, and an electron injection layer, along with the organic emission layer.

The second electrode 682 may include various conductive materials.

A pixel-defining layer PDL is disposed on the second protective insulating layer 672, and the pixel-defining layer PDL is disposed so as not to cover a predetermined region of the first electrode 681, and after that, the intermediate layer 683 is disposed on the region of the first electrode 681, which is not covered by the pixel-defining layer PDL, and the second electrode 682 may be disposed on the intermediate layer 683.

An encapsulation portion 690 may be disposed to protect the display device 680. In an embodiment, the encapsulation portion 690 including one or more encapsulation layers may be disposed on the second electrode 682 so as to block or reduce infiltration of moisture or other foreign substances into the display device 680, for example.

In an embodiment, the encapsulation portion 690 may include a first inorganic encapsulation layer 691, a second inorganic encapsulation layer 692, and an organic encapsulation layer 693, and the organic encapsulation layer 693 may be disposed between the first inorganic encapsulation layer 691 and the second inorganic encapsulation layer 692.

The scan clock line portion 610 disposed in the peripheral area PA may include a plurality of scan clock lines, e.g., first to sixth scan clock lines 611 to 616.

The sensing clock line portion 620 disposed in the peripheral area PA may include a plurality of sensing clock lines, e.g., first to sixth sensing clock lines 621 to 626.

The arrangement of the first to sixth sensing clock lines 621 to 626 of the sensing clock line portion 620 and the arrangement of the first to sixth scan clock lines 611 to 616 of the scan clock line portion 610 in detail may be the same as one of the previous embodiments, e.g., the embodiment shown in FIG. 2.

In some embodiments, the first to sixth sensing clock lines 621 to 626 of the sensing clock line portion 620 and the first to sixth scan clock lines 611 to 616 of the scan clock line portion 610 may include a material that is the same as that included in one or more conductive layers in the display area DA, e.g., the same material as that of one of the electrodes in the thin film transistor disposed in the display area DA, and in more detail, the same material as that of the first connection electrode 654 and the second connection electrode 655.

In an alternative embodiment, each of the first to sixth sensing clock lines 621 to 626 of the sensing clock line portion 620 and the first to sixth scan clock lines 611 to 616 of the scan clock line portion 610 may be electrically connected to lower wirings.

The stage portion 630 may be disposed to be spaced apart from the scan clock line portion 610 and the sensing clock line portion 620, and may be connected via one or more connection lines.

Although not shown in the drawings, the stage portion 630 may include a plurality of stages, e.g., six stages (refer to FIG. 3 as an illustrative embodiment).

In an alternative embodiment, the stage portion 630 may include one or more conductive layers, e.g., a layer including or consisting of the same material as that of one or more conductive layers formed in the display area DA. In more detail, the stage portion 630 may include a layer including or consisting of the same material as that of the first connection electrode 654 and the second connection electrode 655, and a layer including or consisting of the same material as that of the gate electrode 652 or a layer including or consisting of the same material as that of the conductive pattern 677, in detail, one or more thin film transistors.

One or more insulating layers are arranged between the insulating pattern portion 640 and the stage portion 630 and between the scan clock line portion 610 and the sensing clock line portion 620, for example, the first protective insulating layer 671 of the display area DA may be disposed.

In some embodiments, the insulating pattern portion 640 may be formed simultaneously with the insulating layer of the display area DA by the same material as each other. In an embodiment, the insulating pattern portion 640 may include the same material as that of the pixel-defining layer PDL or the second protective insulating layer 672, for example.

In an alternative embodiment, the insulating pattern portion 640 may include a lower layered portion 640a including the same material as that of the second protective insulating layer 672, and an upper layered portion 640b including the same material as that of the pixel-defining layer PDL.

In an alternative embodiment, one or more dams DM1, DM2, and DM3 may be disposed in the peripheral area PA. In an embodiment, the dams DM1, DM2, and DM3 may include a first dam DM1, a second dam DM2, and a third dam DM3. In particular, the second dam DM2 may be disposed between the first dam DM1 and the third dam DM3, for example.

The first dam DM1, the second dam DM2, and the third dam DM3 may be formed by various insulating materials, for example, the one or more dams may include the same material as that of the pixel-defining layer PDL or the second protective insulating layer 672, in more detail, may include a lower layer having the same material as that of the second protective insulating layer 672 and an upper layer having the same material as that of the pixel-defining layer PDL.

In some embodiments, the display apparatus 600 may further include an opposite substrate 603.

The opposite substrate 603 and the substrate 601 may be bonded to each other via the sealing member SLT, and a space generated due to the bonding may be filled with the filling material JCL.

The light conversion layer FTL may be disposed on one surface of the opposite substrate 603, e.g., a surface facing the substrate 601. The light conversion layer FTL is a layer for improving purity of light emitted from the display apparatus 600 and may include a color filter, for example.

In an alternative embodiment, the relatively low refractive index layer LRL may be disposed on the light conversion layer FTL. The relatively low refractive index layer LRL may include an organic material or an inorganic material having relatively low refractive index.

In an alternative embodiment, one or more capping layers CPL may be disposed on one surface of the relatively low refractive index layer LRL. The capping layer CPL may precisely control light characteristics or protect the relatively low refractive index layer LRL, and may include an inorganic insulating material.

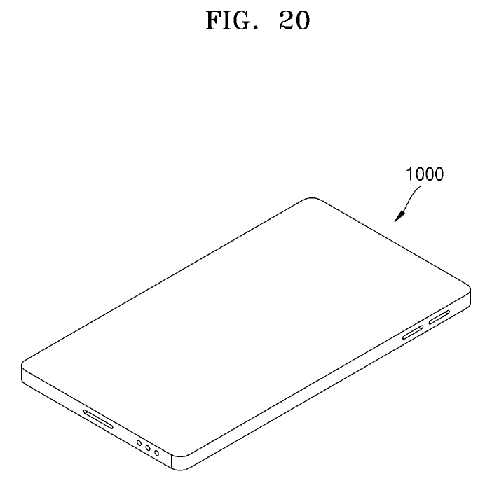

FIG. 20 is a view illustrating an embodiment of an electronic apparatus as a smartphone.

In some embodiments, at least one of the display apparatuses described in the above embodiments may be applied to an electronic apparatus (e.g., smartphone 1000).

In an embodiment, the electronic apparatus may include one or more display apparatuses and other components, for example.

In some embodiments, the electronic apparatus of the embodiment may include at least one of the above-described display apparatuses, and additionally, may include one or more of a processor, a memory, an input module, a power module, an embedded module, and an external module.

The processor may execute software to control at least one other component (e.g., a hardware or software component) of the electronic apparatus connected with the processor and perform data processing or computations. In an embodiment, as at least part of the data processing or computation, the processor may load a command or data received from another component (e.g., an input module, a sensor module, or a communication module) in volatile memory, process the command or the data stored in the volatile memory, and store resulting data in non-volatile memory.

In an alternative embodiment, the processor may include a main processor and an auxiliary processor. The main processor may include at least one of a central processing unit (“CPU”) or an application processor (“AP”). The main processor may further include at least one of a graphic processing unit (“GPU”), a communication processor (“CP”), and an image signal processor (“ISP”). The main processor may further include a neural processing unit (“NPU”). The NPU may be a processor specialized in processing of an artificial intelligence model, and the artificial intelligence model may be generated through machine learning. The artificial intelligence model may include a plurality of artificial neural network layers. The artificial neural network may be one of a deep neural network (“DNN”), a convolutional neural network (“CNN”), a recurrent neural network (“RNN”), a restricted Boltzmann machine (“RBM”), a deep belief network (“DBN”), a bidirectional recurrent DNN (“BRDNN”), a deep Q-network, or a combination of at least two thereof, but is not limited to the embodiments described above. The artificial intelligence model may additionally or alternatively include a software structure in addition to a hardware structure. At least two of the processing units and the processors described above may be implemented as one integrated component (e.g., a single chip), or may be implemented as independent components (e.g., a plurality of chips), respectively.

The auxiliary processor may include a controller, and the controller may include an interface conversion circuit and a timing control circuit. The controller receives an image signal from the main processor, converts a data format of the image signal to meet interface specifications with the display apparatus, and outputs image data. The controller may output various control signals for driving the display apparatus.

In an alternative embodiment, the auxiliary processor may further include a controller, a data converting circuit, a gamma correction circuit, a rendering circuit, etc. The data converting circuit may receive the image data from the controller and may compensate the image data such that the image is displayed with a desired luminance according to characteristics of the electronic apparatus or a user setting or may convert the image data to reduce a power consumption or compensate for afterimages. The gamma correction circuit may convert the image data or a gamma reference voltage such that the image displayed on the electronic apparatus has desired gamma characteristics. The rendering circuit may receive the image data from the controller and may render the image data based on a pixel arrangement of the display apparatus applied to the electronic apparatus.

The input module may receive commands or data used to the components of the electronic apparatus (e.g., processor, sensor module, or sound output module) from the outside of the electronic apparatus (e.g., the user or the external electronic apparatus).

The input module may include a first input module for receiving commands or data from the user and a second input module for receiving commands or data from the external electronic apparatus. The first input module may include a microphone, a mouse, a keyboard, a key (e.g., a button) or a pen (e.g., a passive pen or an active pen). The second input module may support a designated protocol capable of connecting to the external electronic apparatus by wire or wirelessly. In an embodiment, the second input module may include a high-definition multimedia interface (“HDMI”), a universal serial bus (“USB”) interface, a secure digital (“SD”) card interface, or an audio interface. The second input module may include a connector physically connected to the external electronic apparatus, e.g., an HDMI connector, a USB connector, an SD card connector, or an audio connector (e.g., a headphone connector).

In some embodiments, the display apparatus may further include a light emission driver. The light emission driver outputs a light emission control signal that is desired for light emission from the display apparatus in response to a control signal received from the controller. The light emission driver may be formed independently from a scan driver or integrated with the scan driver.

In some embodiments, the display apparatus may include the scan driver receiving a control signal from the controller and outputting scan signals in response to the control signal.

In some embodiments, the display apparatus may include a data driver receiving a control signal from the controller and converting and outputting the image data into an analog voltage in response to the control signal.

The electronic apparatus may further include an embedded module and an external module. The embedded module may include a sensor module, an antenna module, and a sound output module. The external module may include a camera module, a light module, and a communication module.

The sensor module may detect an input by a user's body or an input by an input module, and generate an electrical signal or data value corresponding to the input. The sensor module may include at least one of a fingerprint sensor, an input sensor, and a digitizer. The sensor module may further include a gesture sensor, a gyro-sensor, a pressure sensor, a magnetic sensor, an acceleration sensor, a grip sensor, a proximity sensor, a color sensor, an infrared (“IR”) ray sensor, a vivo sensor, a temperature sensor, a humidity sensor, or an illuminance sensor.

The input module, the sensor module, the camera module, etc., may be used to control the operations of the display apparatus in conjunction with the processor.

The electronic apparatus may be of various types of devices. The electronic apparatus may include a portable communication apparatus (e.g., smartphone), a computer apparatus, a portable multimedia apparatus, a portable medical apparatus, a camera, a wearable device, or a home appliance, for example. The electronic apparatus in the embodiment of the disclosure is not limited to the above stated apparatuses.

The display apparatus and the electronic apparatus including the same in embodiments may easily implement relatively high image-quality characteristics.

While the disclosure has been particularly shown and described with reference to embodiments thereof, it will be understood by those of ordinary skill in the art that various changes in form and details may be made therein without departing from the spirit and scope as defined by the following claims. Therefore, the scope sought to be protected of the disclosure shall be defined by the appended claims.

What is claimed is:

1. A display apparatus comprising:
a substrate;
a display area which implements visible rays on the substrate; and
a peripheral area which is disposed on at least one side of the display area and has a non-display area;
a scan clock line portion including a plurality of scan clock lines arranged sequentially in one direction;
a sensing clock line portion including a plurality of sensing clock lines arranged sequentially in a direction different from the one direction;
a stage portion including a plurality of stages connected to the plurality of scan clock lines and the plurality of sensing clock lines; and
an insulating pattern portion overlapping with the scan clock line portion or the sensing clock line portion.

2. The display apparatus of claim 1, wherein
the scan clock line portion and the sensing clock line portion are arranged in one direction,
the plurality of sensing clock lines of the sensing clock line portion are arranged sequentially in the one direction, and
the plurality of scan clock lines of the scan clock line portion are arranged sequentially in a direction opposite to the one direction.

3. The display apparatus of claim 1, wherein
the scan clock line portion and the sensing clock line portion are arranged in one direction,
a first sensing clock line to an N-th sensing clock line from among the plurality of sensing clock lines are arranged in the one direction, and
a first scan clock line to an N-th scan clock line from among the plurality of scan clock lines are arranged sequentially in a direction opposite to the one direction.

4. The display apparatus of claim 1, wherein
a structure in which the plurality of sensing clock lines of the sensing clock line portion are sequentially arranged is symmetrical with a structure in which the plurality of scan clock lines of the scan clock line portion are sequentially arranged.

5. The display apparatus of claim 1, wherein
a distance between one scan clock line and one sensing clock line which are connected to one of the plurality of stages has a different value from a distance between one scan clock line and one sensing clock line which are connected to another stage of the plurality of stages.

6. The display apparatus of claim 1, wherein
the insulating pattern portion corresponds to a center region between the scan clock line portion and the sensing clock line portion and overlaps with at least some of the plurality of scan clock lines and at least some of the plurality of sensing clock lines.

7. The display apparatus of claim 1, wherein
a center of the insulating pattern portion is misaligned from a center region between the scan clock line portion and the sensing clock line portion.

8. The display apparatus of claim 1, wherein
one or more insulating layers are arranged between the insulating pattern portion and each of the scan clock line portion and the sensing clock line portion.

9. The display apparatus of claim 1, wherein
each of the plurality of stages in the stage portion transfers one or more scan signals and one or more sensing signals to a pixel of the display area by signals received through the plurality of scan clock lines and the plurality of sensing clock lines.

10. An electronic apparatus comprising:
a controller configured to generate one or more signals; and
a display apparatus which receives the one or more signals from the controller and displays information, the display apparatus comprising:
a scan clock line portion including a plurality of scan clock lines which are sequentially arranged in one direction;
a sensing clock line portion including a plurality of sensing clock lines which are sequentially arranged in a direction different from the one direction;
a stage portion including a plurality of stages connected to the plurality of scan clock lines and the plurality of sensing clock lines; and
an insulating pattern portion overlapping with the scan clock line portion or the sensing clock line portion,
wherein the scan clock line portion, the sensing clock line portion and the stage portion receive a signal from the controller and transfer a signal for displaying information on the display apparatus.

11. A display apparatus comprising:
a substrate;
a display area which implements visible rays on the substrate and a peripheral area which is disposed on at least one side of the display area and has a non-display area;
a scan clock line portion including a plurality of scan clock lines arranged sequentially in one direction;
a sensing clock line portion including a plurality of sensing clock lines arranged sequentially in the one direction;
a stage portion including a plurality of stages connected to the plurality of scan clock lines and the plurality of sensing clock lines; and
an insulating pattern portion disposed to overlap with the scan clock line portion or the sensing clock line portion,
wherein, in a region overlapping at least the insulating pattern portion, one sensing clock line is disposed between two scan clock lines next to each other from among the plurality of scan clock lines.

12. The display apparatus of claim 11, wherein
in the region overlapping at least the insulating pattern portion, one scan clock line is disposed between two sensing clock lines next to each other from among the plurality of sensing clock lines.

13. The display apparatus of claim 11, wherein
in the region overlapping at least the insulating pattern portion, each of the plurality of scan clock lines of the scan clock line portion and each of the plurality of sensing clock lines of the sensing clock line portion are sequentially arranged alternately with each other.

14. The display apparatus of claim 11, wherein
the scan clock line portion and the sensing clock line portion are arranged in the one direction,
a first sensing clock line to an N-th sensing clock line from among the plurality of sensing clock lines and a first scan clock line and an N-th scan clock line from among the plurality of scan clock lines are sequentially arranged in the one direction alternately with each other.

15. The display apparatus of claim 11, wherein
the insulating pattern portion corresponds to a center region between the scan clock line portion and the sensing clock line portion and overlaps with at least some of the plurality of scan clock lines and at least some of the plurality of sensing clock lines.

16. The display apparatus of claim 11, wherein
a center of the insulating pattern portion is misaligned from a center region between the scan clock line portion and the sensing clock line portion.

17. The display apparatus of claim 11, wherein
all of the plurality of scan clock lines and all of the plurality of sensing clock lines are sequentially arranged in the one direction alternately with each other.

18. The display apparatus of claim 11, wherein
each of the plurality of stages in the stage portion transfers, to a pixel of the display area, one or more scan signals and one or more sensing signals by signals received through the plurality of scan clock lines and the plurality of sensing clock lines.

19. The display apparatus of claim 18, wherein
the pixel includes one or more organic light-emitting devices which implement visible rays.
